(19) United States
(12) Patent Application Publication
(10) Pub. No.: US 2026/0148785 A1
(43) Pub. Date: May 28, 2026

(54) SEMICONDUCTOR DEVICE AND RECORDING APPARATUS

(71) Applicant: CANON KABUSHIKI KAISHA, Tokyo (JP)

(72) Inventor: YOJI SHIMOYAMA, Kanagawa (JP)

(21) Appl. No.: 19/381,959

(22) Filed: Nov. 6, 2025

(30) Foreign Application Priority Data
Nov. 26, 2024 (JP) 2024-205848

(51) Int. Cl. G11C 17/16; B41J 2/045; G11C 17/18

(52) U.S. Cl. CPC G11C 17/16; B41J 2/04548; B41J 2/0455; B41J 2/04586; G11C 17/18

(57) ABSTRACT

A storage device includes a first semiconductor memory circuit and a second semiconductor memory circuit each including a one-time programmable memory element, with the one-time programmable memory element of the first semiconductor memory circuit being programmed based on information stored in the second semiconductor memory circuit.

### BACKGROUND

### Field of the Technology

The present disclosure relates to a storage device including a semiconductor memory circuit that employs a one-time programmable (OTP) non-volatile memory provided with an antifuse element or a fuse element.

### Description of the Related Art

Recent semiconductor devices employ an OTP memory as a memory element to record product-specific information, including a chip identification (ID) and configuration parameters, after completion of the product. OTP memories include those that employ a fuse element or an antifuse element. The configurations discussed in Japanese Patent No. 6608269 and No. 3537899 are examples of related art that employs an antifuse element or a fuse element.

In the storage device discussed in Japanese Patent No. 6608269, since no programming protection function for the antifuse element is provided, an operational error may cause incorrect information to be programmed.

In the storage device discussed in Japanese Patent No. 3537899, since no protection circuit is provided to prevent adverse effects of electro-static discharge (ESD) on the device, ESD may cause incorrect information to be programmed.

### SUMMARY

The present disclosure provides a storage device configured to prevent erroneous programming of an OTP memory caused by an operational error or electrostatic discharge.

An aspect of the present disclosure provides a storage device that includes a first semiconductor memory circuit including a one-time programmable memory element; and a second semiconductor memory circuit including a one-time programmable memory element. The one-time programmable memory element of the first semiconductor memory circuit is programmed based on information stored in the second semiconductor memory circuit.

Features of the present disclosure will become apparent from the following description of embodiments with reference to the attached drawings. The following description of embodiments is described by way of example.

### BRIEF DESCRIPTION OF THE DRAWINGS

FIG. 1A is a diagram illustrating an example of a semiconductor memory circuit according to a first embodiment.

FIG. 1B is a diagram illustrating an example of a semiconductor memory circuit according to the first embodiment.

FIG. 1C is a diagram illustrating an example of a semiconductor memory circuit according to the first embodiment.

FIG. 2A is a timing diagram illustrating programming and reading operations according to the first embodiment.

FIG. 2B is a timing diagram illustrating programming and reading operations according to the first embodiment.

FIG. 2C is a timing diagram illustrating programming and reading operations according to the first embodiment.

FIG. 2D is a timing diagram illustrating programming and reading operations according to the first embodiment.

FIG. 2E is a timing diagram illustrating programming and reading operations according to the first embodiment.

FIG. 3A is a diagram illustrating an example of a semiconductor memory circuit according to a second embodiment.

FIG. 3B is a diagram illustrating an example of a semiconductor memory circuit according to the second embodiment.

FIG. 3C is a diagram illustrating an example of a semiconductor memory circuit according to the second embodiment.

FIG. 3D is a diagram illustrating an example of a semiconductor memory circuit according to the second embodiment.

FIG. 3E is a diagram illustrating an example of a semiconductor memory circuit according to the second embodiment.

FIG. 3F is a diagram illustrating an example of a semiconductor memory circuit according to the second embodiment.

FIG. 3G is a diagram illustrating an example of a semiconductor memory circuit according to the second embodiment.

FIG. 3H is a diagram illustrating an example of a semiconductor memory circuit according to the second embodiment.

FIG. 3I is a diagram illustrating an example of a semiconductor memory circuit according to the second embodiment.

FIG. 4A is a timing diagram illustrating programming and reading operations according to the second embodiment.

FIG. 4B is a timing diagram illustrating programming and reading operations according to the second embodiment.

FIG. 4C is a timing diagram illustrating programming and reading operations according to the second embodiment.

FIG. 4D is a timing diagram illustrating programming and reading operations according to the second embodiment.

FIG. 4E is a timing diagram illustrating programming and reading operations according to the second embodiment.

FIG. 4F is a timing diagram illustrating programming and reading operations according to the second embodiment.

FIG. 4G is a timing diagram illustrating programming and reading operations according to the second embodiment.

FIG. 4H is a timing diagram illustrating programming and reading operations according to the second embodiment.

FIG. 4I is a timing diagram illustrating programming and reading operations according to the second embodiment.

FIG. 4J is a timing diagram illustrating programming and reading operations according to the second embodiment.

FIG. 4K is a timing diagram illustrating programming and reading operations according to the second embodiment.

FIG. 4L is a timing diagram illustrating programming and reading operations according to the second embodiment.

FIG. 4M is a timing diagram illustrating programming and reading operations according to the second embodiment.

FIG. 5 is a diagram illustrating an example of a semiconductor memory circuit according to a third embodiment.

FIG. 6 is a diagram illustrating an example of a semiconductor memory circuit according to a fourth embodiment.

FIG. 7 is a diagram illustrating an example of a semiconductor memory circuit according to a fifth embodiment.

FIG. 8 is a diagram illustrating an example of a control circuit of a recording apparatus.

FIG. 9 is a diagram illustrating a configuration example of a recording head.

FIG. 10 is a diagram illustrating an example of a recording apparatus.

### DESCRIPTION OF THE EMBODIMENTS

Embodiments of the present disclosure will be described in detail hereinbelow with reference to the drawings.

### First Embodiment

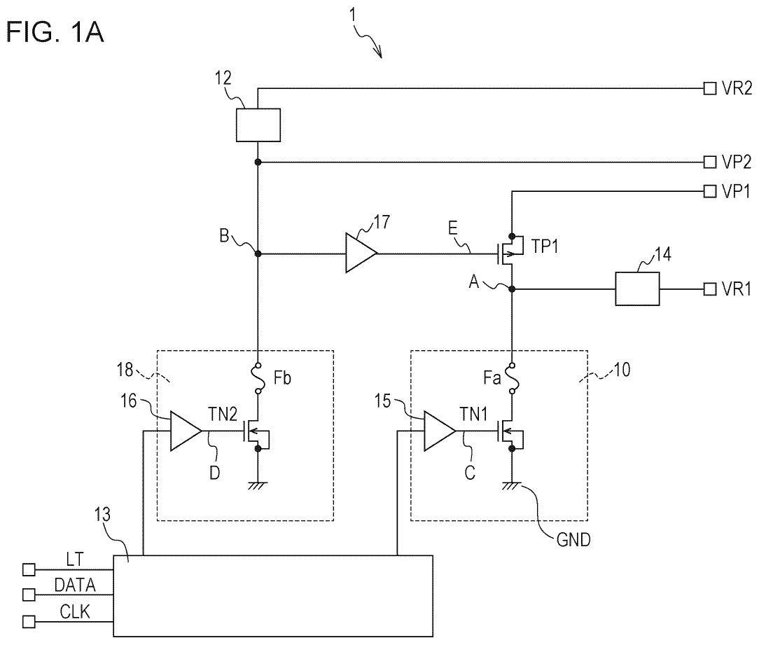

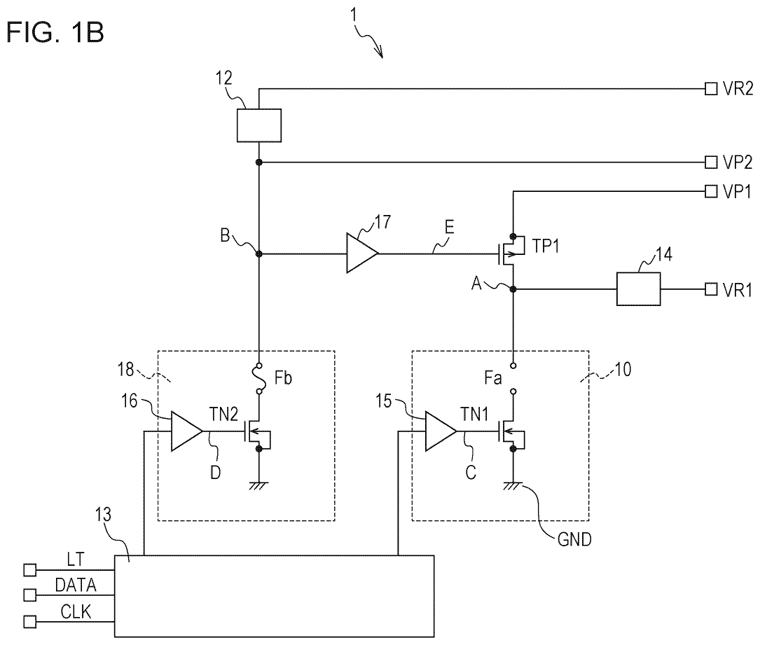

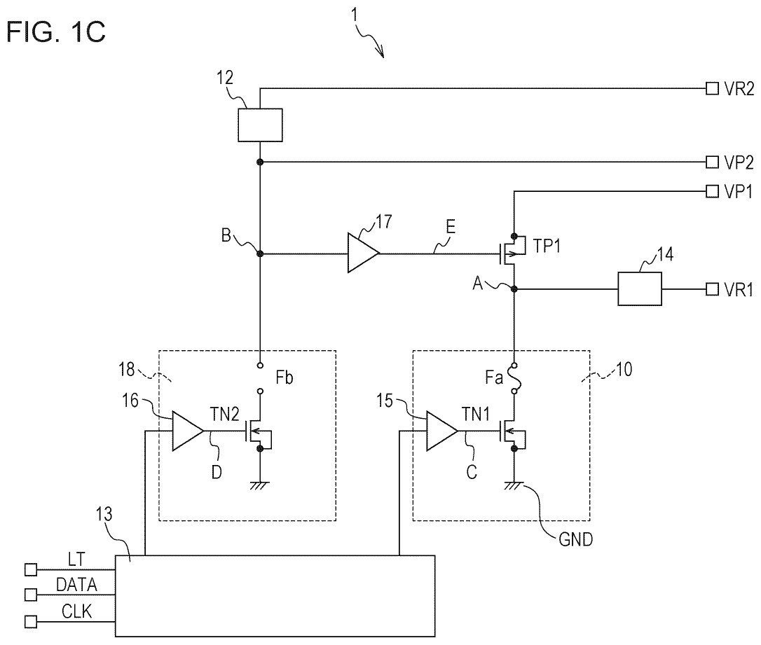

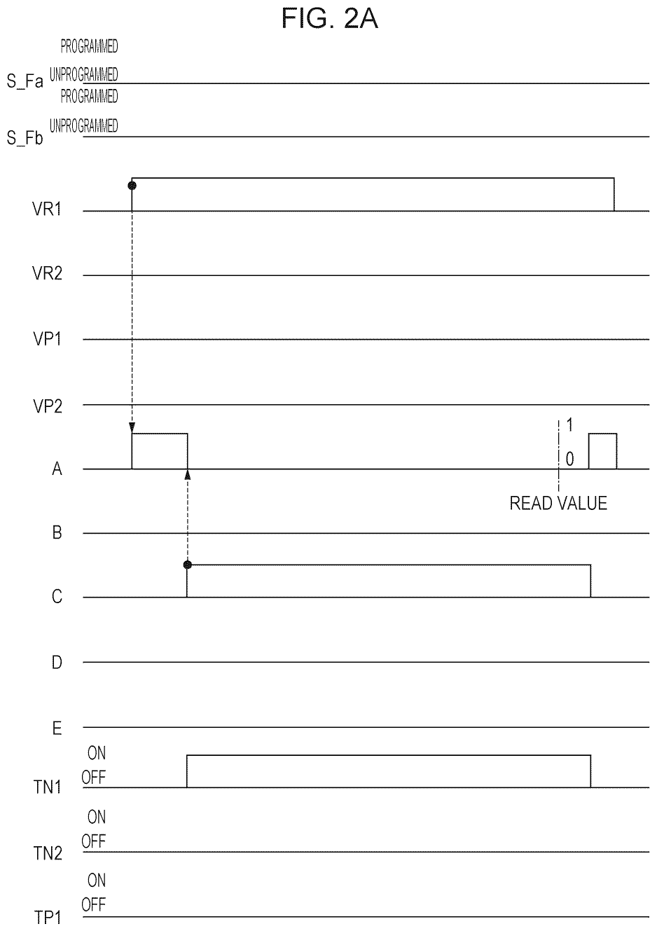

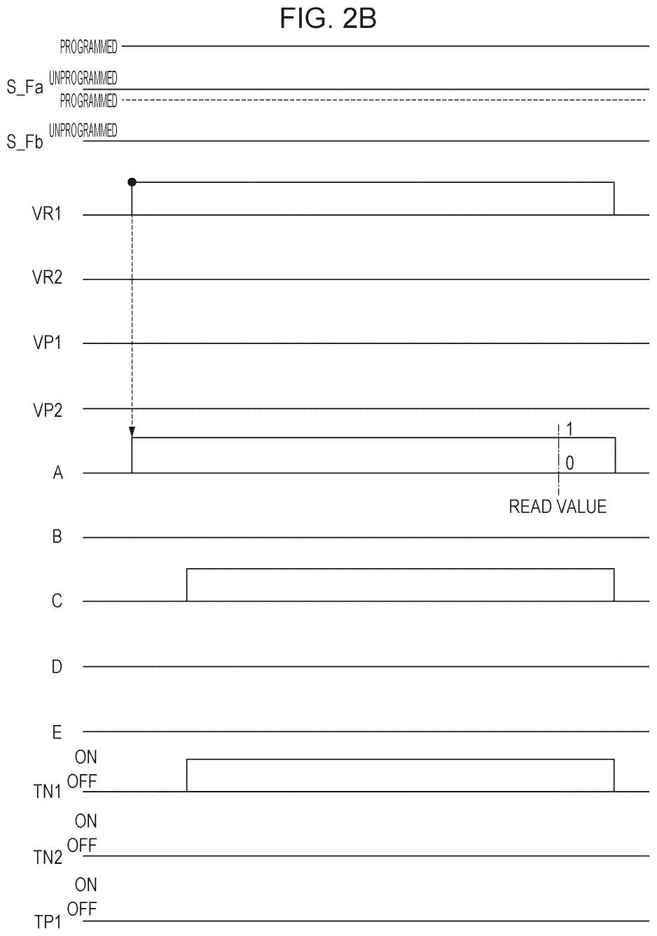

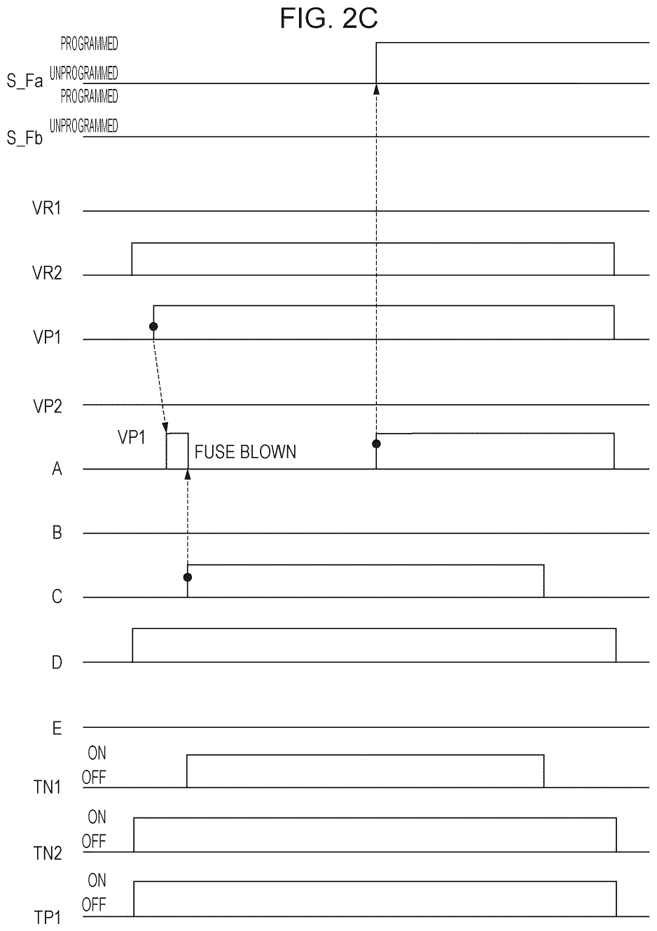

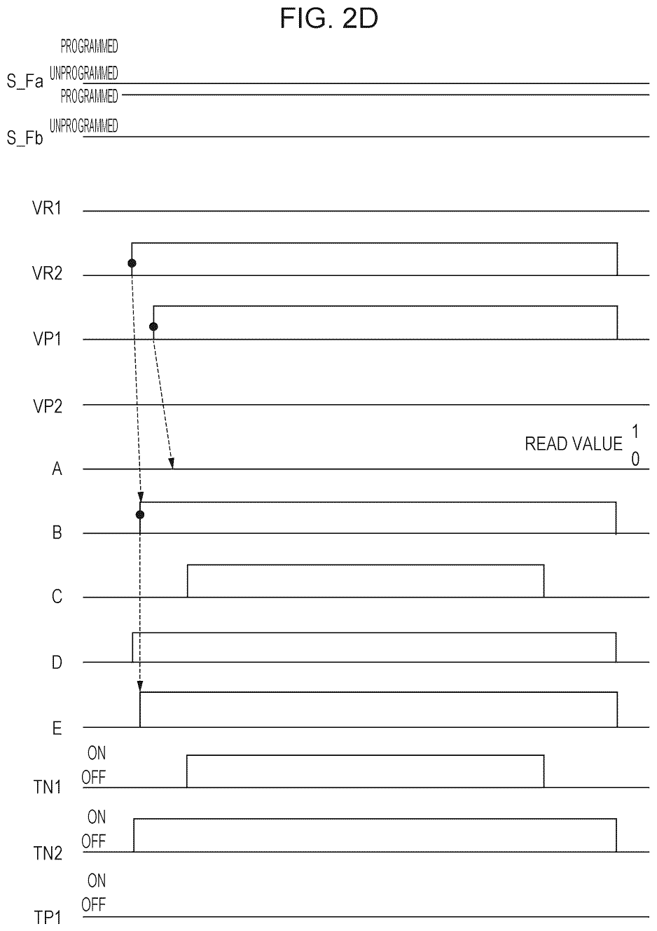

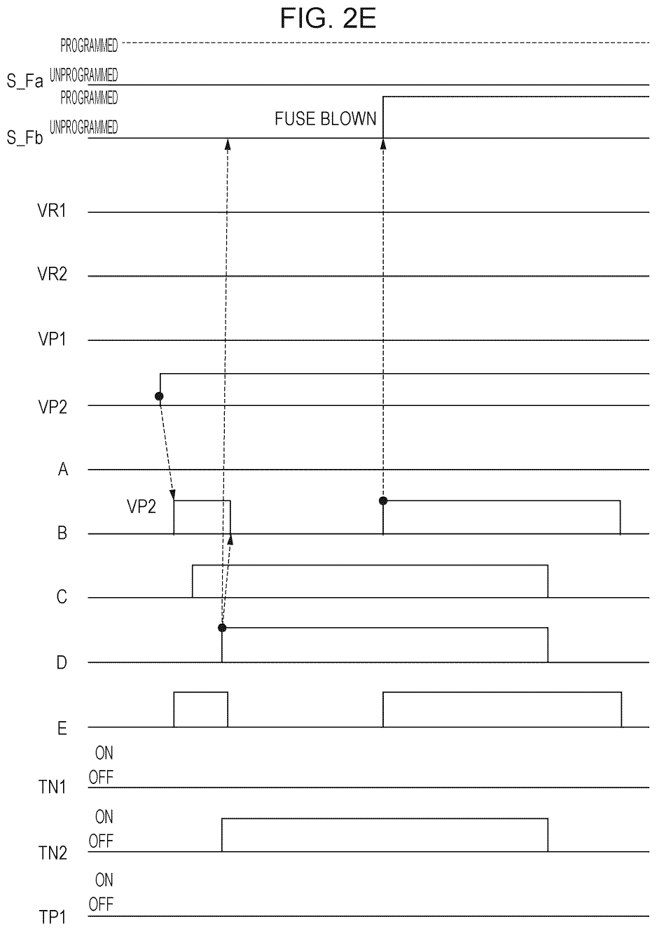

A first embodiment of the present disclosure provides a circuit configuration in which a main memory unit and a programming protection control unit for the main memory unit each employs a fuse element, as an OTP memory element. The first embodiment will be described hereinbelow with reference to FIGS. 1A to 1C and FIGS. 2A to 2E.

FIGS. 1A to 1C illustrate a circuit configuration of a first semiconductor device 1 according to the first embodiment of the present disclosure, showing a state change when information is programmed into the fuse elements.

The first semiconductor device 1 according to the present embodiment includes a first semiconductor memory circuit including a main memory unit 10 having a main memory transistor TN1, a main memory fuse element Fa, a drive voltage conversion element 15 configured to generate a drive voltage for the main memory transistor TN1, and a node C; and a second semiconductor memory circuit including a protection control unit 18 having a protection control transistor TN2, a protection control fuse element Fb, a drive voltage conversion element 16 configured to generate a drive voltage for the protection control transistor TN2, and a node D.

The first semiconductor device 1 includes a read power supply terminal VR1 for the main memory unit 10, a read-power generation circuit 14 for the main memory unit 10, a voltage detection node A for the main memory unit 10, a first programming voltage terminal VP1, a programming control transistor TP1 for the main memory unit 10, a transistor control circuit 17 configured to generate a drive voltage for the programming control transistor TP1, an output voltage detection node E for the transistor control circuit 17, a read power supply terminal VR2 for the protection control unit 18, a read-power generation circuit 12 for the protection control unit 18, a voltage detection node B for the protection control unit 18, and a programming voltage terminal VP2 for the protection control unit 18.

The first semiconductor device 1 includes a shift register 13 configured to generate driving signals for the main memory unit 10 and the protection control unit 18, signals LT, DATA, and CLK for controlling the shift register 13, and a ground wire GND.

In the first semiconductor device 1 using fuse elements as memories, information is recorded depending on whether the fuse elements are in a conductive state or a non-conductive state, where the conductive state indicates an unprogrammed state and the non-conductive state indicates a programmed state.

FIGS. 2A to 2E are timing diagrams showing the operations of the individual elements of the first semiconductor device 1 in chronological order.

The horizontal axis indicates the elapse of time, and the vertical axis indicates the status of the voltage signal of each element.

The voltage signals include S_Fa indicating whether the fuse element Fa is programmed or unprogrammed, S_Fb indicating whether the fuse element Fb is programmed or unprogrammed, the voltage applied to the read power supply terminal VR1, the voltage applied to the read power supply terminal VR2, the voltage applied to the first programming voltage terminal VP1, the voltage applied to the programming voltage terminal VP2, the voltage at the node A, the voltage at the node B, the voltage at the node C, the voltage at the node D, the voltage at the node E, the ON/OFF status of the transistor TN1, the ON/OFF status of the transistor TN2, and the ON/OFF status of the transistor TP1.

When the fuse elements Fa1 and Fa2 are in a short-circuit state corresponding to an unprogrammed state, S_Fa1 and S_Fa2 are indicated as Low, and when the fuse elements Fa1 and Fa2 are in an open state corresponding to a programmed state, S_Fa1 and S_Fa2 are indicated as High.

The individual operations will be described below.

### (1) Reading Operation 1—Initial Reading of Fuse Element Fa

Referring to FIGS. 1A and 2A, the reading operation for the fuse element Fa will be described in a case where S_Fa and S_Fb are Low when the fuse element Fa and the fuse element Fb are in an unprogrammed state.

First, a read voltage is applied to the read power supply terminal VR1 of the main memory unit 10. Then, the voltage at the node A becomes High. Next, by operating the signals LT, DATA, and CLK to control the shift register 13, the output voltage of the drive voltage conversion element 15, which generates a drive voltage for the main memory transistor TN1, is set High, whereby the output voltage at the node C also becomes High.

When the voltage at the node C becomes High, the main memory transistor TN1 is switched to ON, and the voltage at the node A is switched to Low because the fuse element Fa is in a conductive state. The voltage at the node A is read by a voltage read circuit. When the voltage at the node A is Low, the fuse element Fa is determined to be unprogrammed, and when the voltage is High, the fuse element Fa is determined to be programmed. After the voltage at node A is read, the signals LT, DATA, and CLK are operated to control the shift register 13 so that the output voltage of the drive voltage conversion element 15 is set Low, whereby the transistor TN1 is switched to OFF, and the voltage of the read power supply terminal VR1 is also turned OFF.

In this operation, the programmed state of the fuse element Fb does not affect the reading operation.

### (2) Reading Operation 2—Fuse Element Fa Programmed

Referring to FIGS. 1B and 2B, the reading operation for the fuse element Fa will be described in a case where S_Fa is High when the fuse element Fa is in a programmed state, and S_Fb is Low when the fuse element Fb is in an unprogrammed state.

First, a read voltage is applied to the read power supply terminal VR1 of the main memory unit 10. Then, the voltage at the node A becomes High. Next, by operating the signals LT, DATA, and CLK to control the shift register 13, the output voltage of the drive voltage conversion element 15, which generates a drive voltage for the main memory transistor TN1, is set High, whereby the output voltage at the node C also becomes High.

When the voltage at the node C becomes High, the main memory transistor TN1 is switched to ON, but the voltage at the node A remains High because the fuse element Fa is in a non-conductive state. The voltage at the node A is read by a voltage read circuit, and the fuse element Fa is determined to be in a programmed state. After the voltage at the node A is read, the signals LT, DATA, and CLK are operated to control the shift register 13 so that the output voltage of the drive voltage conversion element 15 is set Low, whereby the transistor TN1 is switched to OFF, and the voltage of the read power supply terminal VR1 is also turned OFF.

### (3) Programming Operation 1—Fuse Element Fa—Without Write Protection

Referring to FIGS. 1A and 2C, the programming operation for the fuse element Fa will be described in a case where S_Fa and S_Fb are Low when both the fuse element Fa and the fuse element Fb are in an unprogrammed state.

First, by operating the signals LT, DATA, and CLK to control the shift register 13, the output voltage of the drive voltage conversion element 16, which generates a drive voltage for the protection control transistor TN2, is set High, whereby the output voltage at the node D is set High, and a read voltage is applied to the read power supply terminal VR2 for the protection control unit 18. Then, the transistor TN2 turns ON. Since the fuse element Fb is in a conductive state, but the voltage of the node B remains Low, and the node E also remains Low, the transistor TP1 is switched to ON. Next, when a programming voltage for the fuse element Fa is applied to the first programming voltage terminal VP1, the voltage of the first programming voltage terminal VP1 is applied to the node A. When the signals LT, DATA, and CLK are operated to control the shift register 13, whereby the output voltage of the drive voltage conversion element 15 is set High, in other words, the voltage at the node C is set High, the transistor TN1 turns ON. Since the transistor TN1 turns ON, a current of 70 mA or more flows through the fuse element Fa, whereby the voltage at the node A decreases to 0 V. At that time, the fuse element Fa generates heat, and eventually the fuse element Fa is blown. When the fuse element Fa is blown into an open state corresponding to a programmed state, no current flows through the fuse element Fa, and the voltage at the node A increases to the voltage of the first programming voltage terminal VP1. When the fuse element Fa transitions to a programmed state, S_Fa becomes High. After the fuse element Fa is placed in a programmed state, the signals LT, DATA, and CLK are operated to control the shift register 13, whereby the output voltage of the drive voltage conversion element 15 is set Low and the voltage at the node C is set Low, so that the transistor TN1 turns OFF, and the application of the voltage to the fuse element Fa is stopped. Then, the application of voltages to the read power supply terminal VR2 and the first programming voltage terminal VP1 is stopped, whereby the transistors TN2 and TP1 are turned OFF.

This programming operation causes the circuit to change from the state shown in FIG. 1A to the state shown in FIG. 1B, in which the fuse element Fa is in a programmed state.

### (4) Programming Operation 2—Fuse Element Fa—With Write Protection

Referring to FIGS. 1C and 2D, the programming operation for the fuse element Fa will be described in a case where S_Fa is Low when the fuse element Fa is an unprogrammed state, and S_Fb is high when the fuse element Fb is in a programmed state.

First, by operating the signals LT, DATA, and CLK to control the shift register 13, the output voltage of the drive voltage conversion element 16, which generates a drive voltage for the protection control transistor TN2, is set High, whereby the output voltage at the node D is set High, and a read voltage is applied to the read power supply terminal VR2 for the protection control unit 18. Then, the transistor TN2 turns ON. Since the fuse element Fb is in an open state, the voltage at the node B is set High, and the voltage at the node E is also set High, whereby the transistor TP1 is switched to OFF.

Thereafter, even when a fuse element programming voltage is applied to the first programming voltage terminal VP1, and the signals LT, DATA, and CLK are operated to control the shift register 13, whereby the output voltage of the drive voltage conversion element 15 is set High, and the output voltage at the node C is set High to turn on the transistor TN1, no programming voltage is applied to the fuse element Fa, and therefore, the fuse element Fa cannot be programmed. By operating the signals LT, DATA, and CLK to control the shift register 13, the output voltage of the drive voltage conversion element 15 is set Low, whereby the voltage at the node C is set Low, whereby the transistors TN1 and TN2 are turned OFF, and the application of voltages to the read power supply terminal VR2 and the first programming voltage terminal VP1 is stopped.

In this manner, when the fuse element Fb has already been programmed, no programming voltage is applied to the fuse element Fa, thereby protecting the fuse element Fa from being programmed.

### (5) Protection Memory Programming Operation

Referring to FIGS. 1A and 2E, the programming operation for the fuse element Fb will be described in a case where S_Fa and S_Fb are Low when the fuse element Fa and the fuse element Fb are both in an unprogrammed state.

First, when a fuse element programming voltage is applied to the programming voltage terminal VP2, the voltage of the programming voltage terminal VP2 is applied to the node B. Next, by operating the signals LT, DATA, and CLK to control the shift register 13, the output voltage of the drive voltage conversion element 16 is set High, whereby the output voltage at the node D is set High. Then, the transistor TN2 turns ON. Since the transistor TN2 turns ON, a current of 70 mA or more flows through the fuse element Fb, whereby the voltage at the node B decreases to 0 V. At that time, the fuse element Fb generates heat, and eventually the fuse element Fb is blown. When the fuse element Fb is blown into an open state corresponding to a programmed state, no current flows through the fuse element Fb, and the voltage at the node B increases to the voltage of the programming voltage terminal VP2. When the fuse element Fb transitions to a programmed state, S_Fb becomes High. After the fuse element Fb is placed in a programmed state, the signals LT, DATA, and CLK are operated to control the shift register 13, whereby the output voltage of the drive voltage conversion element 16 is set Low, whereby the voltage at the node D becomes Low, so that the transistor TN2 turns OFF, and the application of the voltage to the fuse element Fb is stopped. Then, the application of the voltage to the programming voltage terminal VP2 is stopped.

This programming operation causes the circuit to change from the state shown in FIG. 1A to the state shown in FIG. 1C, in which the fuse element Fb is in a programmed state.

Thus, programming of the OTP memory can be controlled by hardware, thereby protecting the programming information of the OTP memory from being erroneously programmed caused by an operational error or ESD.

### Second Embodiment

A second embodiment of the present disclosure illustrates a circuit configuration in which multiple fuse elements or antifuse elements, which are OTP memories, are used as OTP memory elements for each of a main memory unit and a programming protection control unit for the main memory unit. A semiconductor device can thus be implemented which includes a rewritable main memory unit that uses a plurality of OTP memories according to the present embodiment, wherein protection by a programming protection control unit and cancellation of the protection can be switched multiple times, and information can be rewritten.

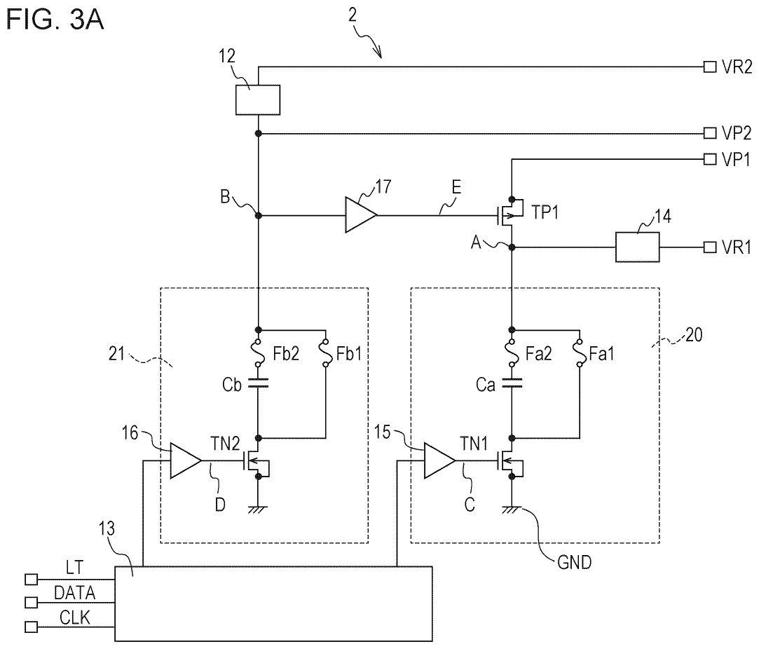

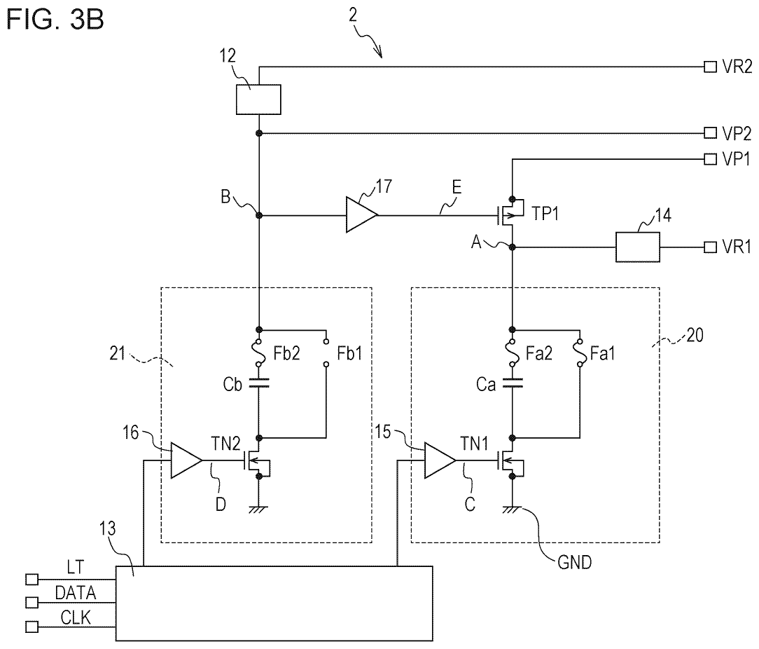

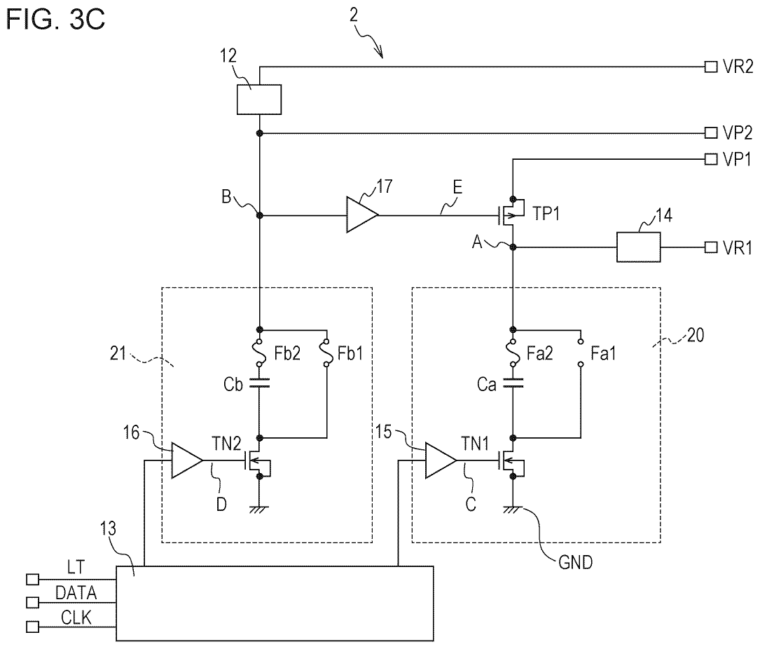

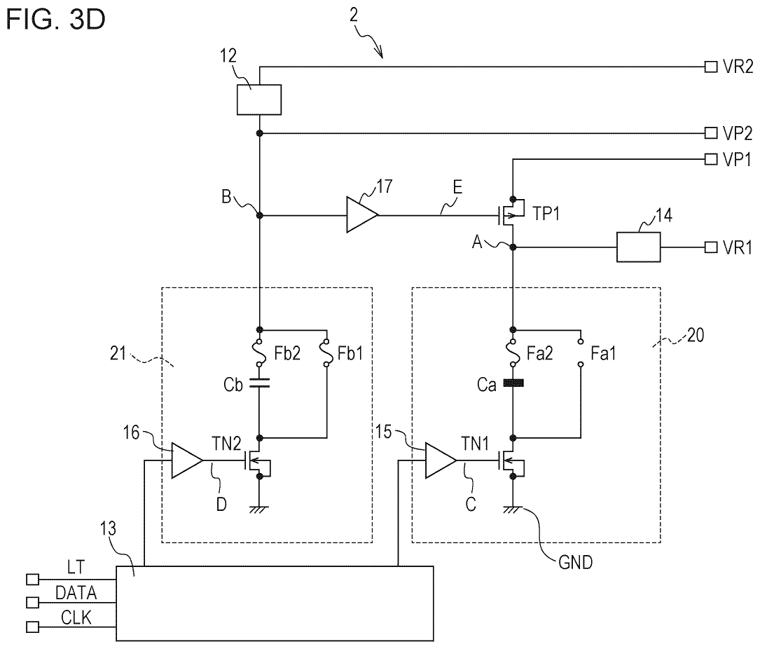

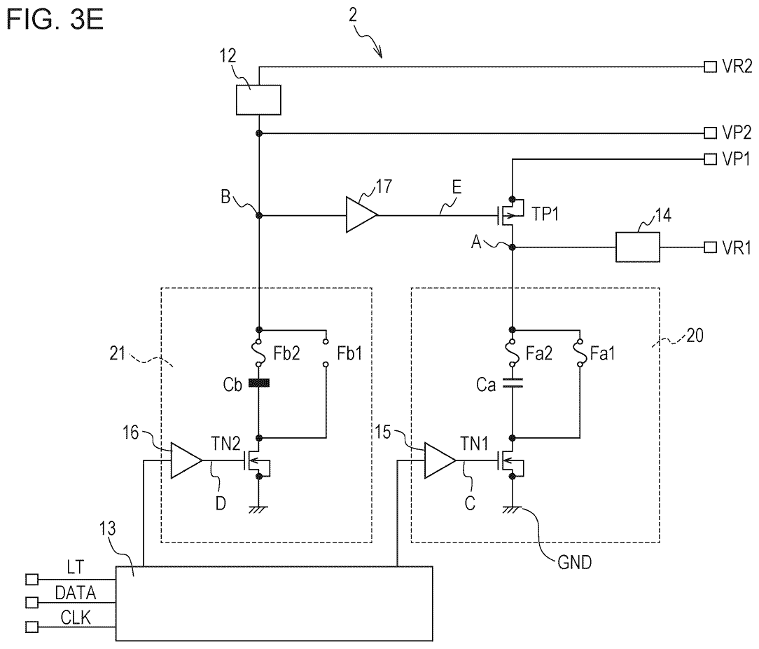

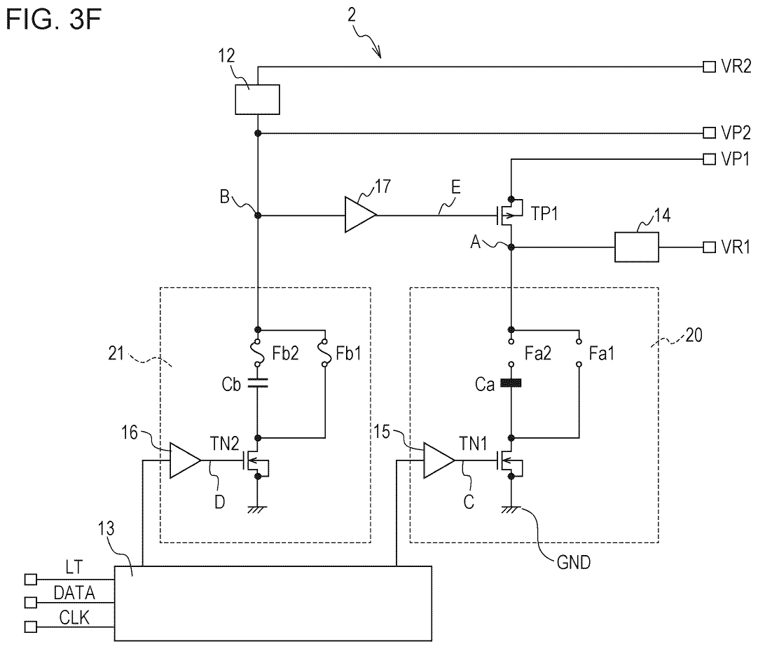

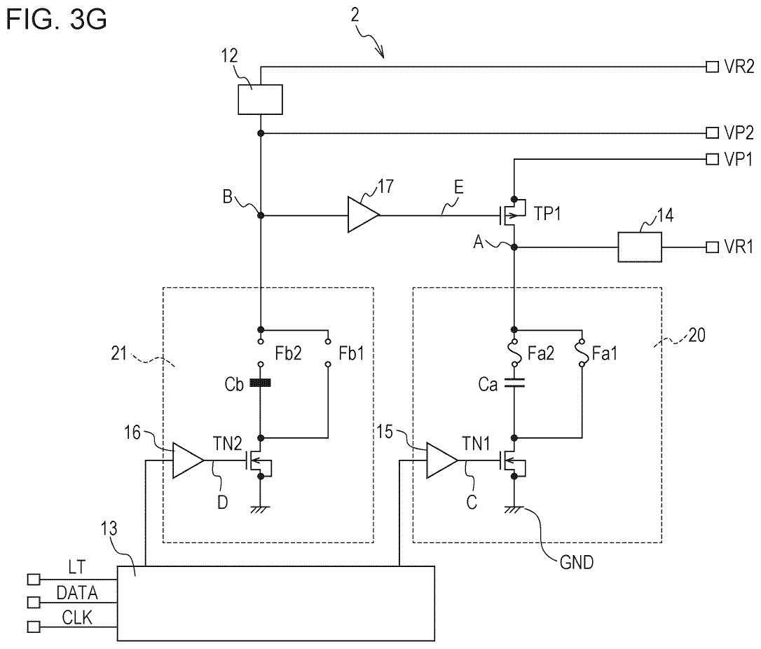

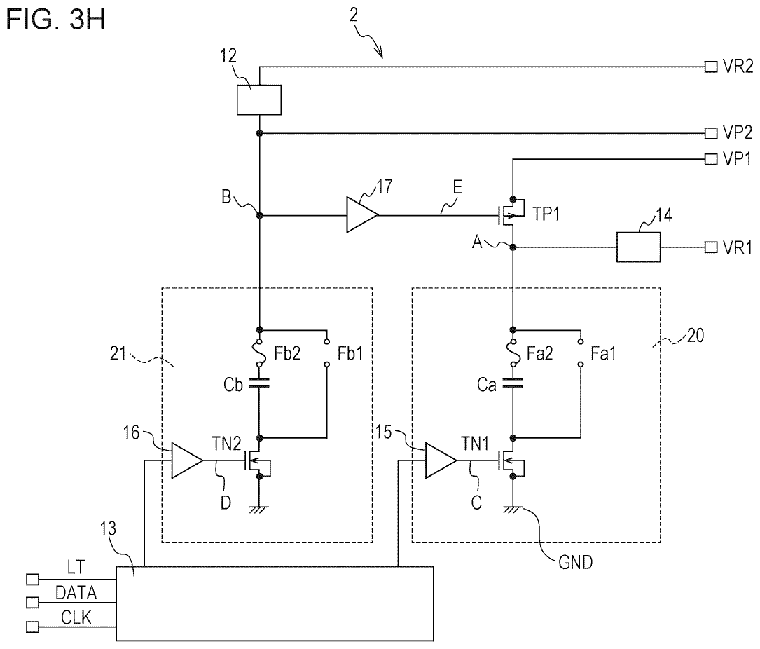

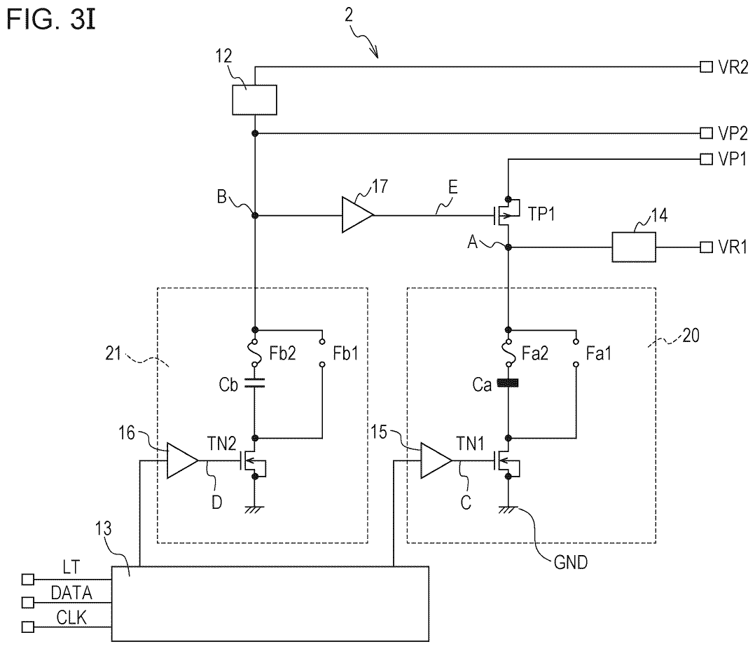

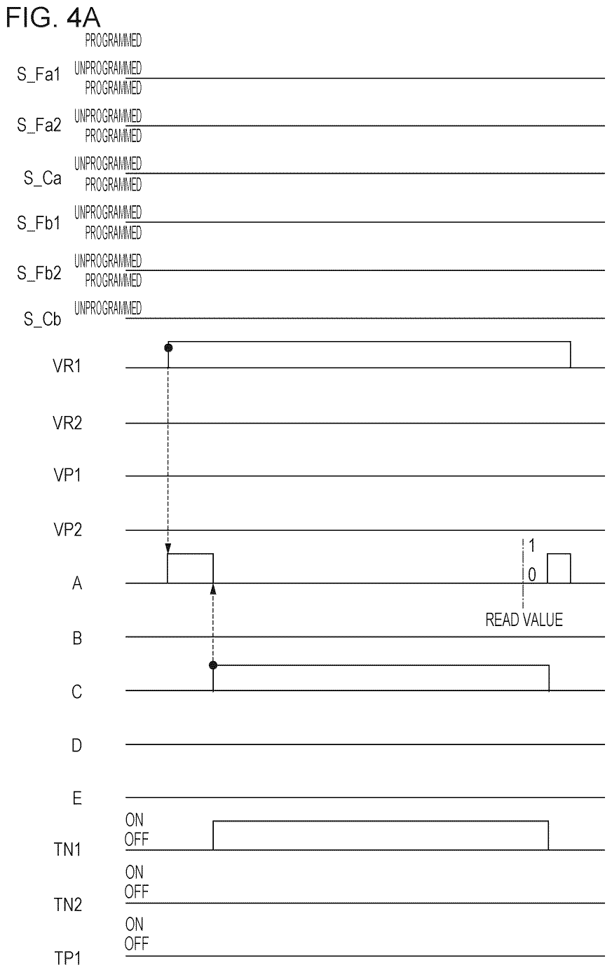

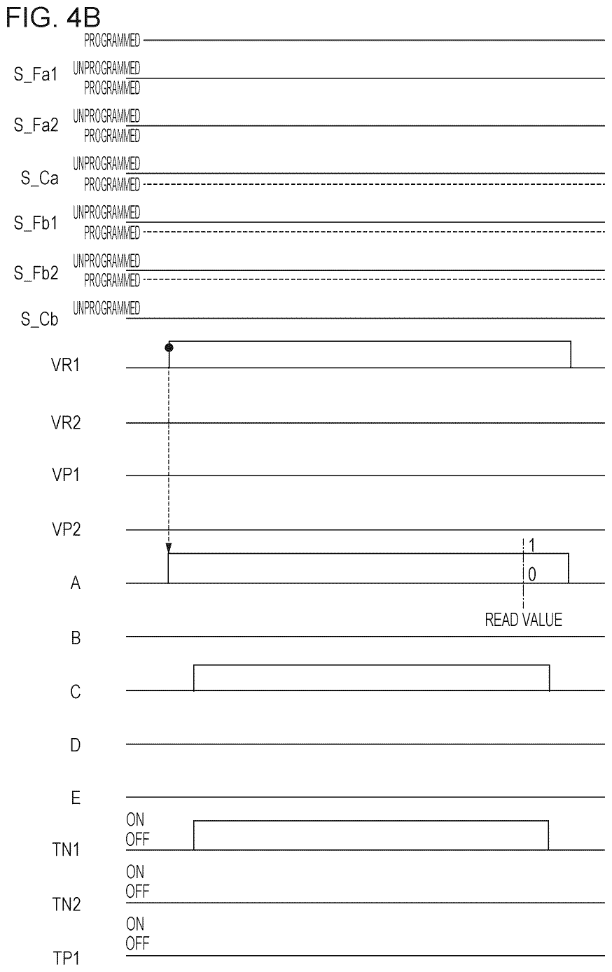

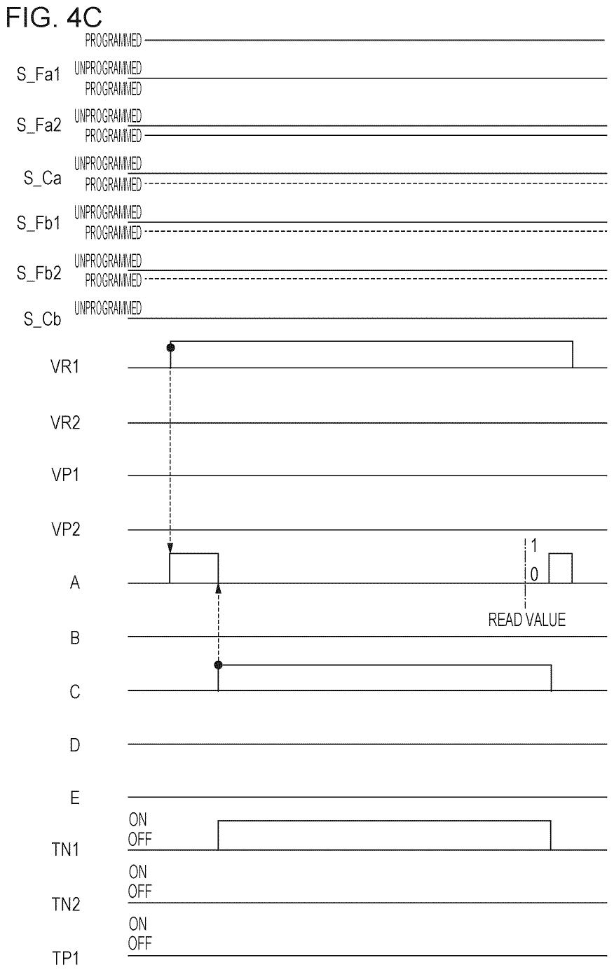

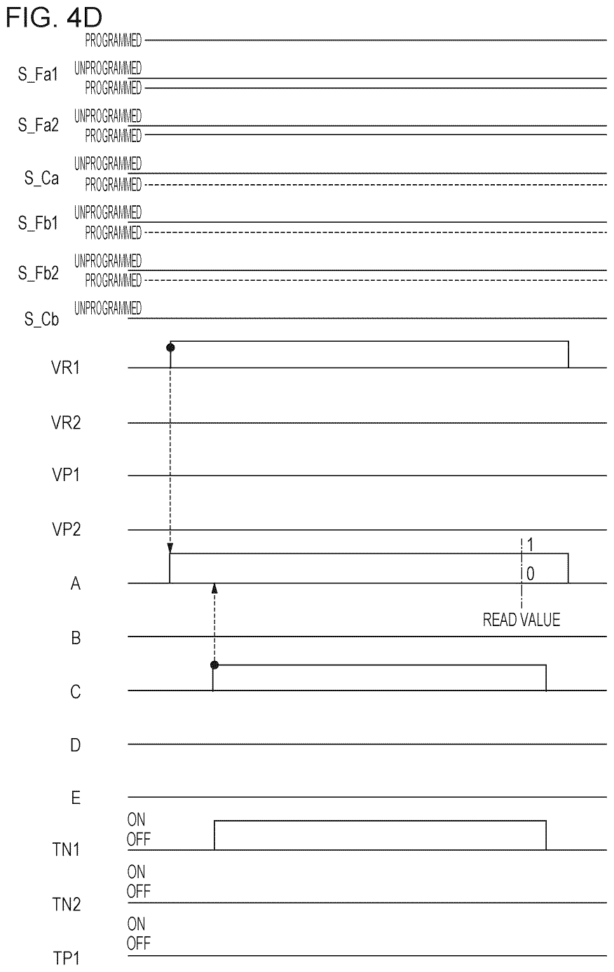

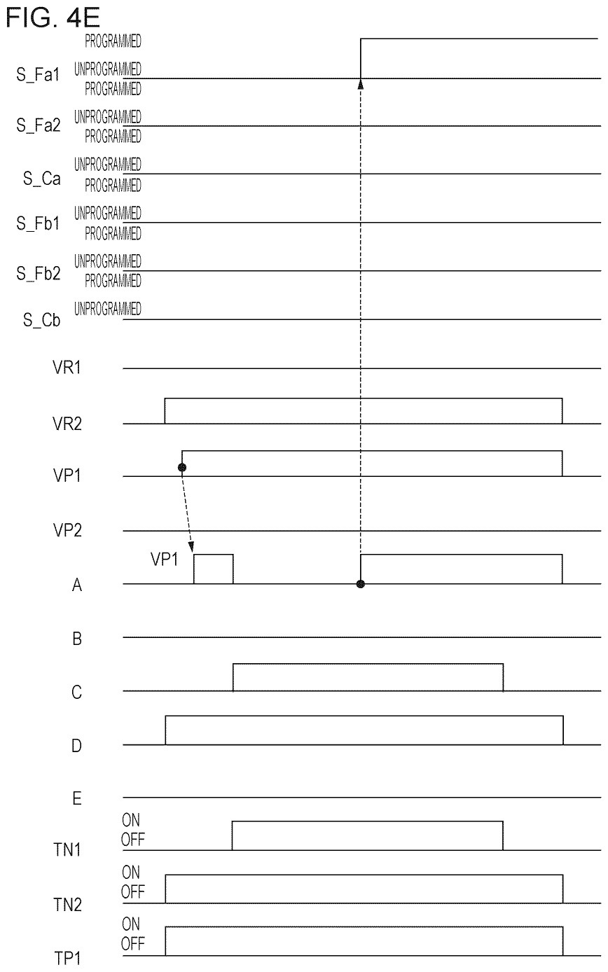

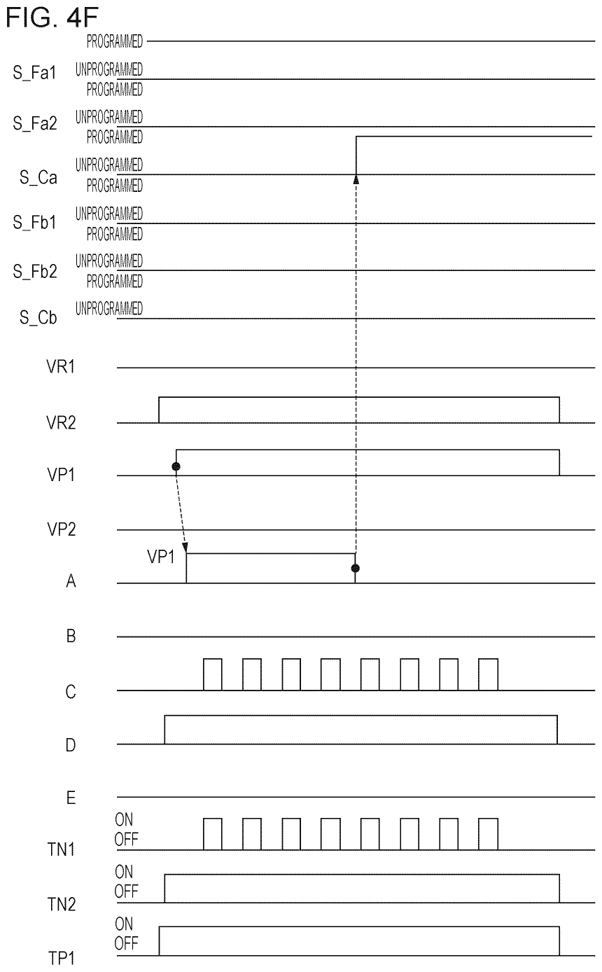

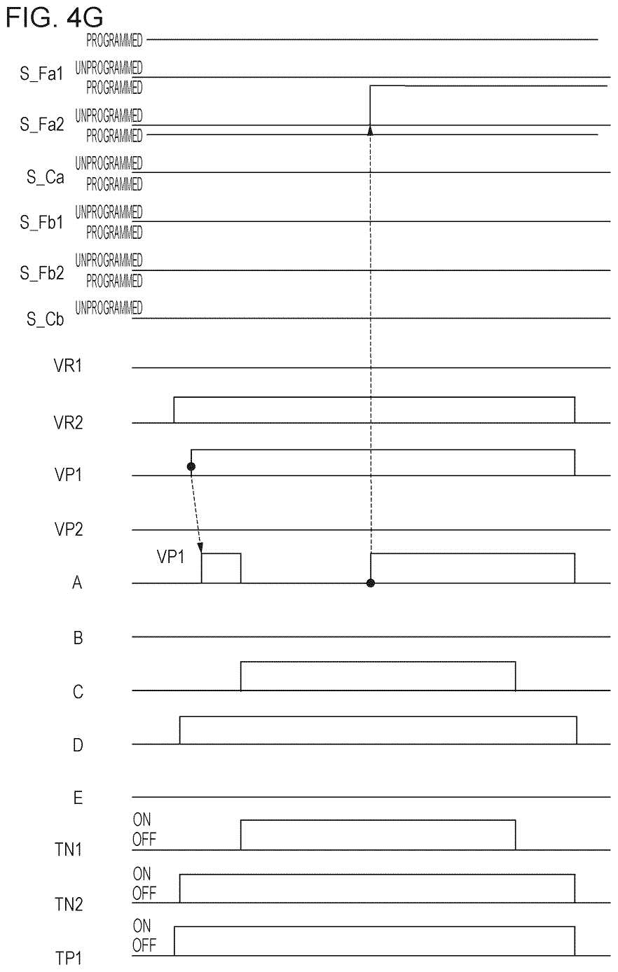

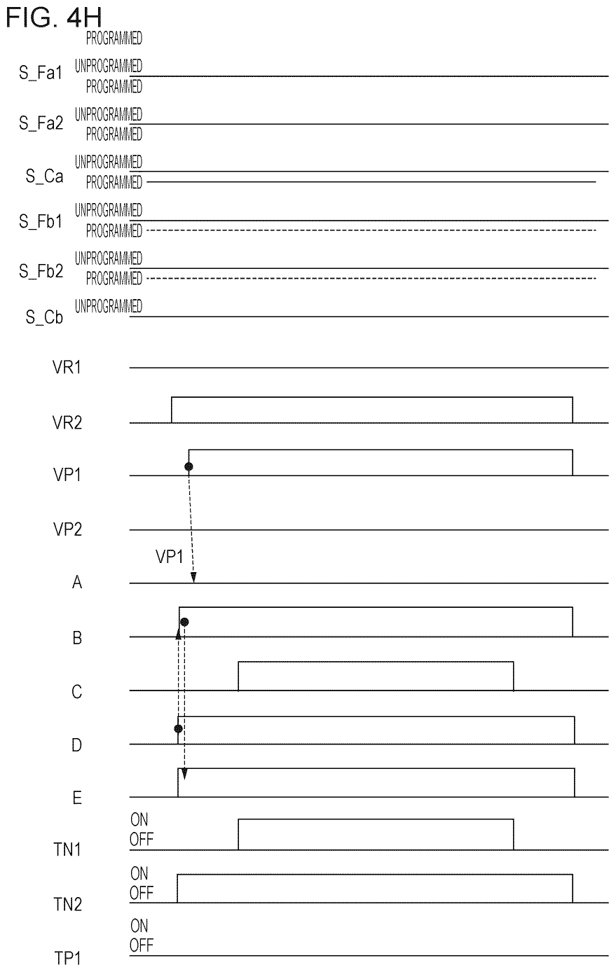

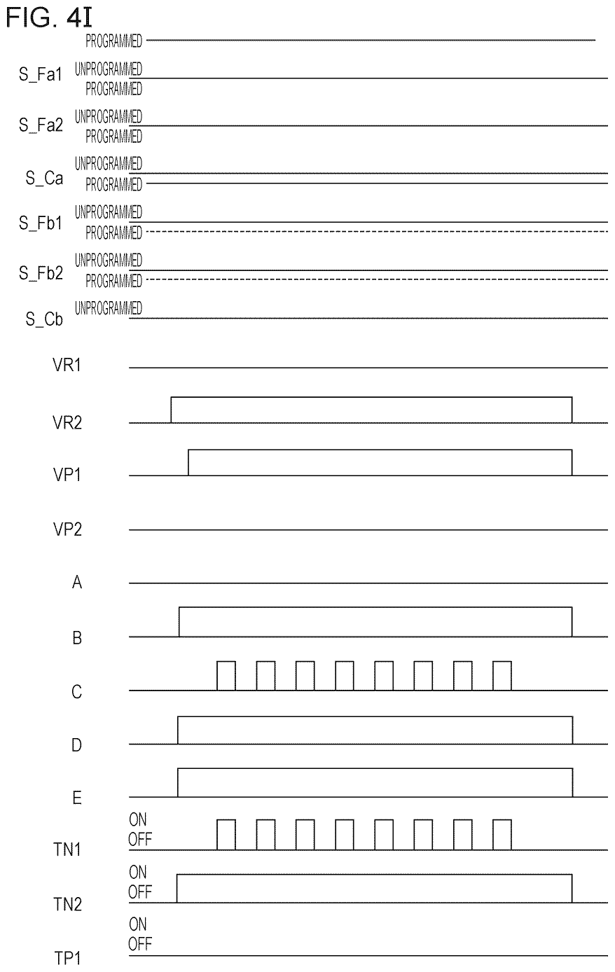

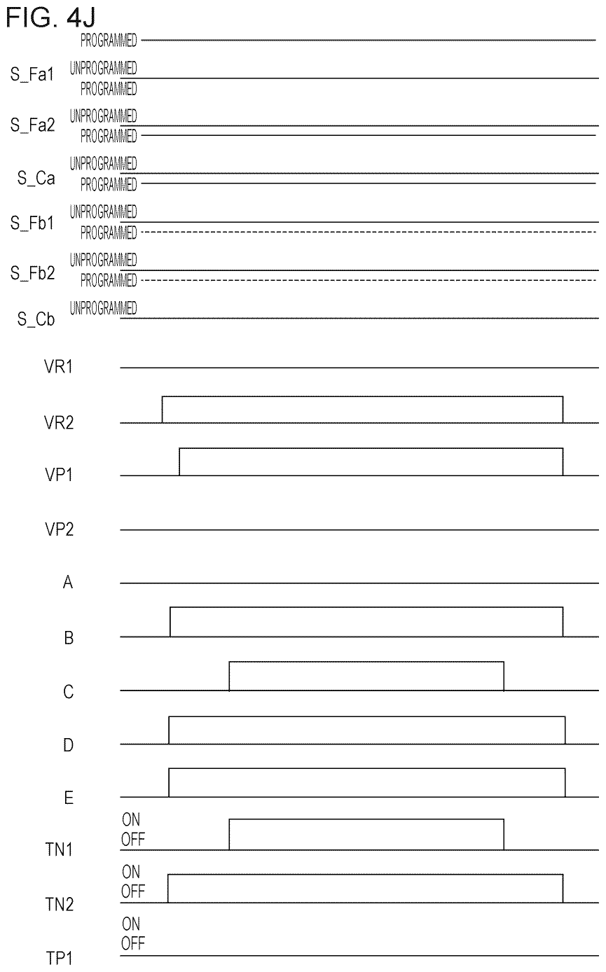

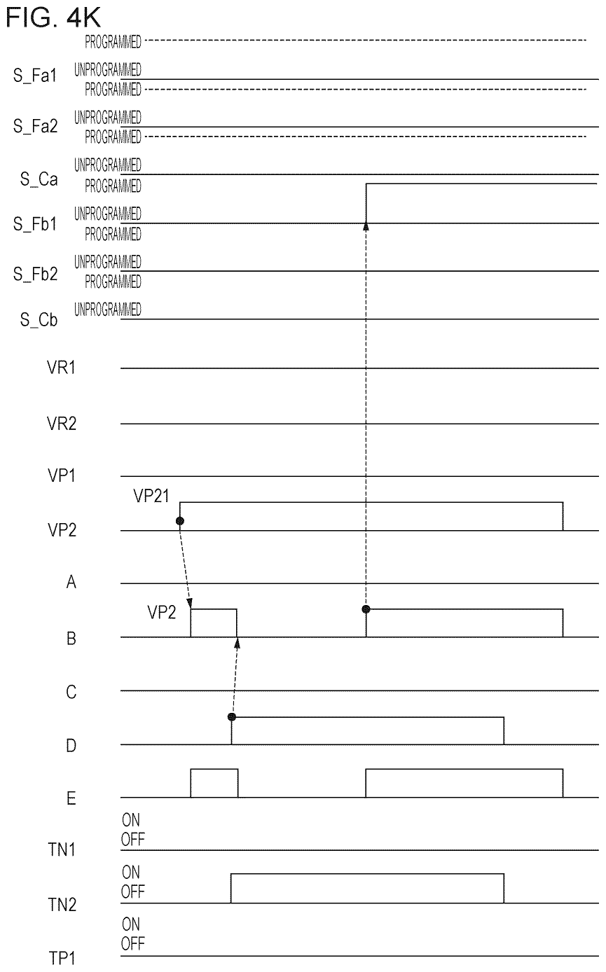

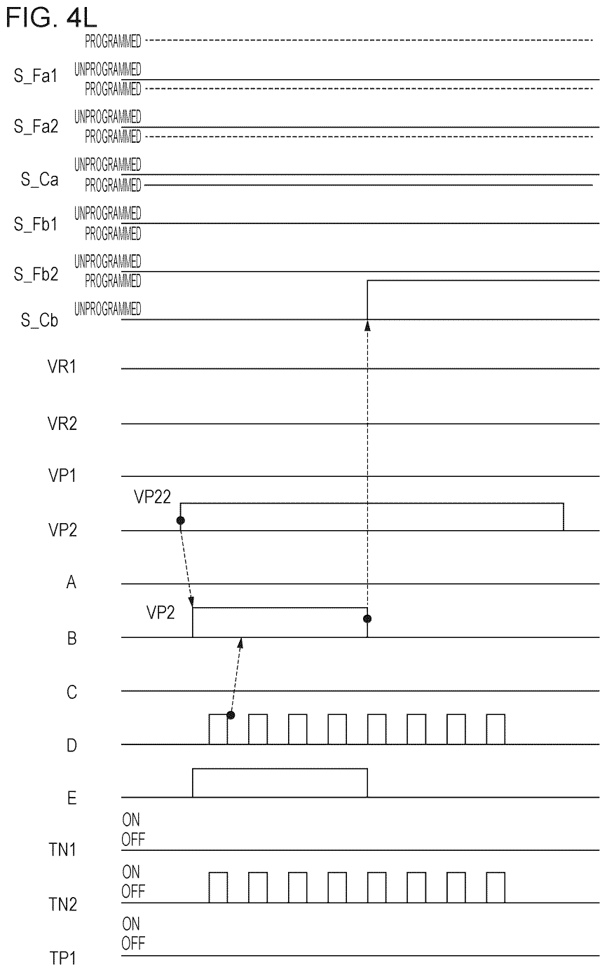

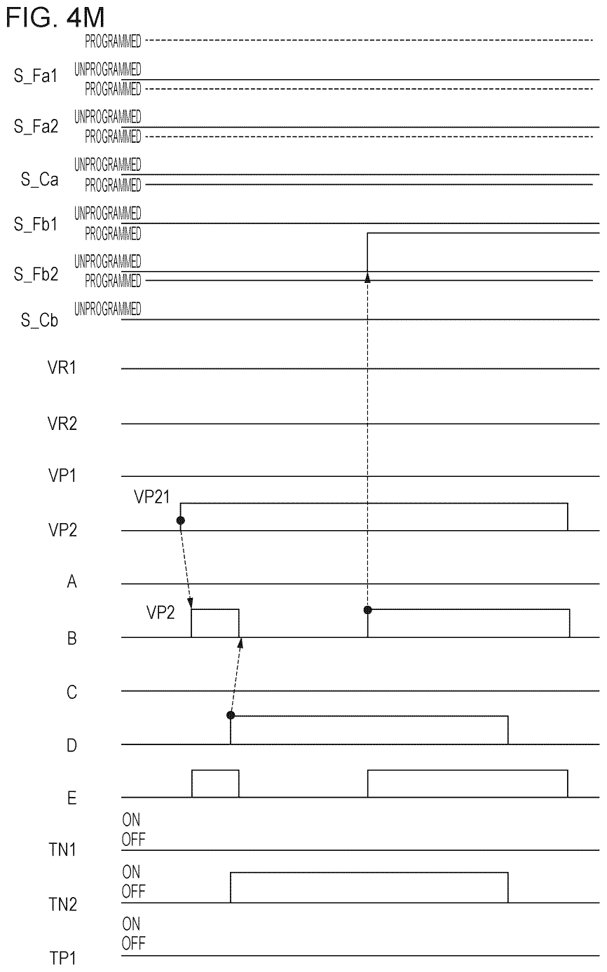

The second embodiment of the present disclosure will be described with reference to FIGS. 3A to 3I and FIGS. 4A to 4M.

FIG. 3A to FIG. 3I illustrate the circuit configuration of a second semiconductor device 2 according to the second embodiment of the present disclosure, showing a state change when information is programmed into the fuse elements.

The second semiconductor device 2 according to the present embodiment includes a first semiconductor memory circuit including a main memory unit 20 having a main memory transistor TN1, a first main memory fuse element Fa1, a second main memory fuse element Fa2, a main memory antifuse element Ca, a drive voltage conversion element 15 configured to generate a drive voltage for the main memory transistor TN1, and a node C; and a second semiconductor memory circuit including a programming protection control unit 21 having a protection control transistor TN2, a first protection control fuse element Fb1, a second protection control fuse element Fb2, a protection control antifuse element Cb, a drive voltage conversion element 16 configured to generate a drive voltage for the protection control transistor TN2, and a node D.

The second semiconductor device 2 includes a read power supply terminal VR1 for the main memory unit 20, a read-power generation circuit 14 for the main memory unit 20, a voltage detection node A for the main memory unit 20, a first programming voltage terminal VP1, a programming control transistor TP1 for the main memory unit 20, a transistor control circuit 17 configured to generate a drive voltage for the transistor TP1, an output voltage detection node E for the transistor control circuit 17, a read power supply terminal VR2 for the protection control unit 21, a read-power generation circuit 12 for the protection control unit 21, a voltage detection node B for the protection control unit 21, and a programming voltage terminal VP2 for the protection control unit 21.

The second semiconductor device 2 includes a shift register 13 configured to generate driving signals for the main memory unit 20 and the protection control unit 21, signals LT, DATA, and CLK for controlling the shift register 13, and a ground wire GND.

In the second semiconductor device 2 using fuse elements or antifuse elements as memories, information is recorded depending on whether the fuse elements are in a conductive state or a non-conductive state. In the case of fuse elements, the conductive state indicates an unprogrammed state and the non-conductive state indicates a programmed state, whereas in the case of antifuse elements, the conductive state indicates a programmed state and the non-conductive state indicates an unprogrammed state.

FIGS. 4A to 4M are timing diagrams showing the operations of the individual elements of the second semiconductor device 2 in chronological order.

The horizontal axis indicates the elapse of time, and the vertical axis indicates the status of the voltage signal of each element.

The voltage signals include S_Fa1 indicating the programmed state of the fuse element Fa1, S_Fa2 indicating the programmed state of the fuse element Fa2, S_Fb1 indicating the programmed state of the fuse element Fb1, S_Fb2 indicating the programmed state of the fuse element Fb2, S_Ca indicating the programmed state of the antifuse element Ca, S_Cb indicating the programmed state of the antifuse element Cb, the voltage applied to the read power supply terminal VR1, the voltage applied to the read power supply terminal VR2, the voltage applied to the programming voltage terminal VP1, the voltage applied to the programming voltage terminal VP2, the voltage at the node A, the voltage at the node B, the voltage at the node C, the voltage at the node D, the voltage at the node E, the ON/OFF status of the transistor TN1, the ON/OFF status of the transistor TN2, and the ON/OFF status of the transistor TP1.

When the fuse elements Fa1,⋅Fa2,⋅Fb1,⋅and Fb2 are in a short-circuit state corresponding to an unprogrammed state, S_Fa1, S_Fa2, S_Fb1, and S_Fb2 are indicated as Low, and when the fuse elements Fa1,⋅Fa2,⋅Fb1, and⋅Fb2 are in an open state corresponding to a programmed state, S_Fa1, S_Fa2, S_Fb1, and S_Fb2 are indicated as High.

When the antifuse elements Ca and Cb are in an open state corresponding to an unprogrammed state, S_Ca and S_Cb are indicated as Low, and when the antifuse elements Ca and Cb are in a short-circuit state corresponding to a programmed state, S_Ca and S_Cb are indicated as High.

The individual operations will be described below.

### (1) Reading Operation 1—Main Memory Unit—Initial Reading

Referring to FIGS. 3A and 4A, the reading operation of the main memory unit 20 will be described in a case where S_Fa1, S_Fa2, S_Fb1, S_Fb2, S_Ca, and S_Cb are Low when the fuse elements Fa1, Fa2, Fb1, and Fb2 and the antifuse elements Ca and Cb are in an unprogrammed state.

First, a read voltage is applied to the read power supply terminal VR1. Then, the voltage at the node A becomes High. Next, by operating the signals LT, DATA, and CLK to control the shift register 13, the output voltage of the drive voltage conversion element 15 is set High, whereby the output voltage at the node C also becomes High. When the voltage at the node C becomes High, the transistor TN1 turns ON, whereby the voltage at the node A becomes Low because the fuse element Fa1 is in a conductive state. The voltage at the node A is read by a voltage read circuit. When the voltage at the node A is Low, the main memory unit 20 is determined to be unprogrammed, and when the voltage is High, the main memory unit 20 is determined to be in a programmed state. Therefore, in this case, the main memory unit 20 is determined to be unprogrammed. After the main memory unit 20 has been read, by operating the signals LT, DATA, and CLK to control the shift register 13, the output voltage of the drive voltage conversion element 15 is set Low, whereby the transistor TN1 is switched to OFF, and the voltage of the read power supply terminal VR1 is turned OFF.

Since the programmed state of the programming protection control unit 21 does not affect the reading operation of the main memory unit 20, signals S_Fb1, S_Fb2, and S_Cb in FIG. 4A are indicated by the dotted lines.

### (2) Reading Operation 2—Fuse Element Fa1 Programmed

Referring to FIGS. 3C and 4B, the reading operation of the main memory unit 20 will be described in a case where S_Fa1 is High when the fuse element Fa1 is in a programmed state, and S_Fa2, S_Fb1, S_Fb2, S_Ca, and S_Cb are Low when the fuse elements Fa2, Fb1, and Fb2 and the antifuse elements Ca and Cb are in an unprogrammed state.

First, a read voltage is applied to the read power supply terminal VR1. Then, the voltage at the node A becomes High. Next, by operating the signals LT, DATA, and CLK to control the shift register 13, the output voltage of the drive voltage conversion element 15 is set High, whereby the output voltage at the node C also becomes High. When the voltage at the node C becomes High, the transistor TN1 is turned to ON, and the voltage at the node A remains High because the fuse element Fa1 is in a non-conductive state. The voltage at the node A is read by a voltage read circuit. Since the voltage at the node A is High, the main memory unit 20 is determined to be in a programmed state. After the main memory unit 20 is read, by operating the signals LT, DATA, and CLK to control the shift register 13, the output voltage of the drive voltage conversion element 15 is set Low, whereby the transistor TN1 is switched to OFF, and the voltage of the read power supply terminal VR1 is also turned OFF.

Since the programmed state of the programming protection control unit 21 does not affect the reading operation of the main memory unit 20, signals S_Fb1, S_Fb2, and S_Cb in FIG. 4B are indicated by the dotted lines.

### (3) Reading Operation 3—Fuse Element Fa1 and Antifuse Element Ca Programmed

Referring to FIGS. 3D and 4C, the reading operation of the main memory unit 20 will be described in a case where S_Fa1 and S_Ca are High when the fuse element Fa1 and the antifuse element Ca are in a programmed state, and S_Fa2, S_Fb1, S_Fb2, and S_Cb are Low when the fuse elements Fa2, Fb1, and Fb2 and the antifuse element Cb are in an unprogrammed state.

First, a read voltage is applied to the read power supply terminal VR1. Then, the voltage at the node A becomes High. Next, by operating the signals LT, DATA, and CLK to control the shift register 13, the output voltage of the drive voltage conversion element 15 is set High, whereby the output voltage at the node C also becomes High. When the voltage at the node C becomes High, the transistor TN1 turns ON. Since the fuse element Fa2 and the antifuse element Ca are in a conductive state, the voltage at the node A becomes Low.

The voltage at the node A is read by a voltage read circuit. Since the voltage at the node A is Low, the main memory unit 20 is determined to be in a programmed state. After the main memory unit 20 is read, by operating the signals LT, DATA, and CLK to control the shift register 13, the output voltage of the drive voltage conversion element 15 is set Low, whereby the transistor TN1 is turned OFF, and the voltage of the read power supply terminal VR1 is also turned OFF.

Since the programmed state of the programming protection control unit 21 does not affect the reading operation of the main memory unit 20, signals S_Fb1, S_Fb2, and S_Cb in FIG. 4C are indicated by the dotted lines.

### (4) Reading Operation 4—Fuse Elements Fa1 and Fa2 and Antifuse Element Ca Programmed

Referring to FIGS. 3F and 4D, the reading operation of the main memory unit 20 will be described in a case where S_Fa1, S_Fa2, and S_Ca are High when the fuse elements Fa1 and Fa2 and the antifuse element Ca are in a programmed state, and S_Fb1, S_Fb2, and S_Cb are Low when the fuse elements Fb1 and Fb2 and the antifuse element Cb are in an unprogrammed state.

First, a read voltage is applied to the read power supply terminal VR1. Then, the voltage at the node A becomes High. Next, by operating the signals LT, DATA, and CLK to control the shift register 13, the output voltage of the drive voltage conversion element 15 is set High, whereby the output voltage at the node C also becomes High. When the voltage at the node C becomes High, the transistor TN1 turns ON. Since the fuse elements Fa1 and Fa2 are in a non-conductive state, the voltage at the node A remains High. The voltage at the node A is read by a voltage read circuit. Since the voltage at the node A is High, the main memory unit 20 is determined to be in a programmed state. After the main memory unit 20 is read, by operating the signals LT, DATA, and CLK to control the shift register 13, the output voltage of the drive voltage conversion element 15 is set Low, whereby the transistor TN1 is turned OFF, and the voltage of the read power supply terminal VR1 is also turned OFF.

Since the programmed state of the programming protection control unit 21 does not affect the reading operation of the main memory unit 20, signals S_Fb1, S_Fb2, and S_Cb in FIG. 4D are indicated by the dotted lines.

### (5) Programming Operation 1—Programming of Fuse Element Fa1—Without Write Protection

Referring to FIGS. 3A and 4E, the programming operation of the fuse element Fa1 will be described in a case where S_Fa1, S_Fa2, S_Fb1, S_Fb2, S_Ca, and S_Cb are Low when the fuse elements Fa1, Fa2, Fb1, and Fb2 and the antifuse elements Ca and Cb are in an unprogrammed state.

First by operating the signals LT, DATA, and CLK to control the shift register 13, the output voltage of the drive voltage conversion element 16 is set High, whereby the output voltage at the node D is set High, thereby applying a read voltage to the read power supply terminal VR2. Then, the transistor TN2 turns ON. Since the fuse element Fb1 is in a conductive state, the voltage at the node B remains Low, and the voltage at the node E also remains Low, and the transistor TP1 is switched to ON. Next, when a fuse element programming voltage is applied to the first programming voltage terminal VP1, the voltage of the first programming voltage terminal VP1 is applied to the node A. Then, by operating the signals LT, DATA, and CLK to control the shift register 13, the output voltage of the drive voltage conversion element 15 is set High, in other words, the voltage at the node C is set High, whereby the transistor TN1 turns ON. Since the transistor TN1 turns ON, a current of 70 mA or more flows through the fuse element Fa1, whereby the voltage at the node A decreases to 0 V. At that time, the fuse element Fa1 generates heat, and eventually the fuse element Fa1 is blown. When the fuse element Fa1 is blown into an open state corresponding to a programmed state, S_Fa1 becomes High, no current flows through the fuse element Fa1, and the voltage at the node A increases to the voltage of the first programming voltage terminal VP1. After the fuse element Fa1 is placed in a programmed state, the signals LT, DATA, and CLK are operated to control the shift register 13, whereby the output voltage of the drive voltage conversion element 15 is set Low and the voltage at the node C is set Low, so that the transistor TN1 is turned OFF, and the application of the voltage to the fuse element Fa1 is stopped. Then, the application of voltages to the read power supply terminal VR2 and the first programming voltage terminal VP1 is stopped, whereby the transistors TN2 and TP1 are turned OFF. This programming operation causes the circuit to change from the state shown in FIG. 3A to the state shown in FIG. 3C, in which the fuse element Fa1 is in a programmed state.

### (6) Programming Operation 2—Programming of Antifuse Element Ca—Without Write Protection

Referring to FIGS. 3C and 4F, the programming operation of the antifuse element Ca will be described in a case where S_Fa1 is High when the fuse element Fa1 is in a programmed state, and S_Fa2, S_Fb1, S_Fb2, S_Ca, and S_Cb are Low when the fuse elements Fa2, Fb1, and Fb2 and the antifuse elements Ca and Cb are in an unprogrammed state.

First, by operating the signals LT, DATA, and CLK to control the shift register 13, the output voltage of the drive voltage conversion element 16 is made High, and the output voltage at the node D is made High, whereby a read voltage is applied to the read power supply terminal VR2. Then, the transistor TN2 turns ON. Since the fuse element Fb1 is in a conductive state, the voltage at the node B remains Low, and the voltage at the node E also remains Low, and the transistor TP1 turns ON. Next, when an antifuse element programming voltage is applied to the first programming voltage terminal VP1, the voltage of the first programming voltage terminal VP1 is applied to the node A. Then, by operating the signals LT, DATA, and CLK to control the shift register 13, the output voltage of the drive voltage conversion element 15 is set High, that is, the voltage at the node C is set High, and the transistor TN1 turns ON. Since the transistor TN1 turns ON, the voltage of the first programming voltage terminal VP1 is applied to the antifuse element Ca. Furthermore, by operating the signals LT, DATA, and CLK to control the shift register 13, the output voltage of the drive voltage conversion element 15 is set Low, in other words, the voltage at the node C is set Low, whereby the transistor TN1 is turned OFF, thereby removing the voltage applied to the antifuse element Ca. In the programming of the antifuse element Ca, an operation of applying a voltage to the antifuse element Ca for a predetermined time and then removing the applied voltage is repeatedly performed at a frequency of, for example, about 6 MHz, until the antifuse element Ca undergoes hard breakdown. When the antifuse element Ca undergoes hard breakdown, a current of about 10 to 30 mA flows, whereby the voltage at the node A decreases to the GND potential, and the programming of the antifuse element Ca completes.

At that time, S_Ca is set High. After a lapse of a predetermined time, by operating the signals LT, DATA, and CLK to control the shift register 13, the output voltages of the drive voltage conversion elements 15 and 16 are set Low, whereby the transistors TN1 and TN2 are turned OFF, and the application of the voltages to the programming voltage terminals VP1 and the read power supply terminal VR2 is stopped.

By performing this programming operation, the circuit changes from the state shown in FIG. 3C to the state shown in FIG. 3D in which the fuse element Fa1 and the antifuse element Ca are in a programmed state.

### (7) Programming Operation 3—Programming of Fa2—Without Write Protection

Referring to FIGS. 3D and 4G, a programming operation of the fuse element Fa2 will be described in a case where S_Fa1 and S_Ca are High when the fuse element Fa1 and the antifuse element Ca are in a programmed state, and S_Fa2, S_Fb1, S_Fb2, and S_Cb are Low when the fuse elements Fa2, Fb1, and Fb2 and the antifuse element Cb are in an unprogrammed state.

First, by operating the signals LT, DATA, and CLK to control the shift register 13, the output voltage of the drive voltage conversion element 16 is set High, and the output voltage at the node D is set High, whereby a read voltage is applied to the read power supply terminal VR2. Then, the transistor TN2 turns ON. Since the fuse element Fb1 is in a conductive state, the voltage at the node B remains Low, and the voltage at the node E also remains Low, and the transistor TP1 is switched to ON. Next, when a fuse element programming voltage is applied to the first programming voltage terminal VP1, the voltage of the first programming voltage terminal VP1 is applied to the node A. Then, by operating the signals LT, DATA, and CLK to control the shift register 13, the output voltage of the drive voltage conversion element 15 is set High, in other words, the voltage at the node C is set High, whereby the transistor TN1 turns ON. Since the transistor TN1 turns ON, a current of 70 mA or more flows through the fuse element Fa2, and the voltage at the node A decreases to 0 V. At that time, the fuse element Fa2 generates heat, and eventually the fuse element Fa2 is blown. When the fuse element Fa2 is blown into an open state corresponding to a programmed state, no current flows through the fuse element Fa2, and the voltage at the node A increases to the voltage of the first programming voltage terminal VP1. At that time, S_Fa2 becomes High. After the fuse element Fa2 is placed in a programmed state, the signals LT, DATA, and CLK are operated to control the shift register 13, whereby the output voltage of the drive voltage conversion element 15 is set Low and the voltage at the node C is set Low, so that the transistor TN1 is turned OFF, and the application of the voltage to the fuse element Fa2 is stopped. Then, the application of voltages to the read power supply terminal VR2 and the first programming voltage terminal VP1 is stopped, whereby the transistors TN2 and TP1 are turned OFF. This programming operation causes the circuit to change from the state shown in FIG. 3D to the state shown in FIG. 3F, in which the fuse element Fa2 is in a programmed state.

### (8) Programming Operation 4—Programming of Fuse Element Fa1—Write Protection Enabled

Referring to FIG. 4H, the programming operation of the fuse element Fa1 in the case of FIG. 3B where S_Fa1, S_Fa2, S_Fb2, S_Ca, and S_Cb are Low when the fuse elements Fa1, Fa2, and Fb2 and the antifuse elements Ca and Cb are in an unprogrammed state, and S_Fb1 is High when only the fuse element Fb1 is in a programmed state or in the case of FIG. 3G where S_Fa1, S_Fa2, and S_Ca are Low when the fuse elements Fa1 and Fa2 and the antifuse element Ca are in an unprogrammed state, and S_Fb1, S_Fb2, and S_Cb are High when the fuse elements Fb1 and Fb2 and the antifuse element Cb are in a programmed state.

First, by operating the signals LT, DATA, and CLK to control the shift register 13, the output voltage of the drive voltage conversion element 16 is set High, and the output voltage at the node D is set High, whereby a read voltage is applied to the read power supply terminal VR2. Then, the transistor TN2 turns ON. Since the fuse element Fb1 or Fb2 is in a non-conductive state, the voltage at the node B becomes High, and the voltage at the node E also becomes High, so that the transistor TP1 remains OFF without being switched to ON. Therefore, even by applying a fuse element programming voltage to the programming voltage terminal VP1 and operating the signals LT, DATA, and CLK to control the shift register 13, the output voltage of the drive voltage conversion element 15 is set High, whereby the transistor TN1 is switched to ON, no programming voltage can be applied to the main memory unit 20, whereby the fuse element Fa1 is not programmed. By operating the signals LT, DATA, and CLK to control the shift register 13, the output voltages of the drive voltage conversion elements 15 and 16 are set Low, and the voltages at the nodes C and D are set Low, whereby the transistors TN1 and TN2 are turned OFF and the application of voltages to the read power supply terminal VR2 and the programming voltage terminal VP1 is stopped.

In this manner, when the fuse element Fb1 is in a programmed state as in FIG. 3B or when the fuse elements Fb1 and Fb2 are in a programmed state as in FIG. 3G, the fuse element Fa1 cannot be programmed, whereby the information can be protected.

### (9) Programming Operation 5—Programming of Antifuse Element Ca—Write Protection Enabled

Referring to FIG. 4I, the programming operation of the antifuse element Ca will be described in the case of FIG. 3H in which S_Fa2, S_Fb2, S_Ca, and S_Cb are Low when the fuse elements Fa2 and Fb2 and the antifuse elements Ca and Cb are in an unprogrammed state, and S_Fa1 and S_Fb1 are High when the fuse elements Fa1 and Fb1 are in a programmed state.

First, by operating the signals LT, DATA, and CLK to control the shift register 13, the output voltage of the drive voltage conversion element 16 is set High, whereby the output voltage at the node D is set High, and a read voltage is applied to the read power supply terminal VR2. Then, the transistor TN2 turns ON. Since the fuse element Fb1 is in a non-conductive state, the voltage at the node B becomes High, and the voltage at the node E also becomes High, so that the transistor TP1 remains OFF without being switched to ON. Therefore, even when a fuse element programming voltage is applied to the programming voltage terminal VP1, no programming voltage can be applied to the main memory unit 20. For this reason, even by operating the signals LT, DATA, and CLK to control the shift register 13, such that the output voltage of the drive voltage conversion element 15 is cyclically changed from High to Low and the transistor TN1 is shifted from ON to OFF, the antifuse element Ca cannot be programmed. By operating the signals LT, DATA, and CLK to control the shift register 13, the output voltages of the drive voltage conversion elements 15 and 16 are set Low, and the voltages at the nodes C and D are set Low, whereby the transistors TN1⋅and TN2 are turned OFF, and the application of voltages to the read power supply terminal VR2 and the programming voltage terminal VP1 is stopped.

Thus, when the fuse element Fb1 is in a programmed state, the antifuse element Ca cannot be programmed, whereby the information can be protected.

Even when the fuse elements Fb1 and Fb2 and the antifuse element Cb are in a programmed state, no programming voltage can be applied to the main memory unit 20, whereby the antifuse element Ca can be protected from being programmed.

### (10) Programming Operation 6—Programming of Fuse Element Fa2—Write Protection Enabled

Referring to FIG. 4J, a programming operation of the fuse element Fa2 will be described in the case of FIG. 3I in which S_Fa2, S_Fb2, and S_Cb are Low when the fuse elements Fa2 and Fb2 and the antifuse element Cb are in an unprogrammed state, and S_Fa1, S_Fb1, and S_Ca are High when only the fuse elements Fa1 and Fb1 and the antifuse element Ca are in a programmed state.

First, by operating the signals LT, DATA, and CLK to control the shift register 13, the output voltage of the drive voltage conversion element 16 is set High, and the output voltage at the node D is set High, whereby a read voltage is applied to the read power supply terminal VR2. Then, the transistor TN2 turns ON. Since the fuse element Fb1 is in a non-conductive state, the voltage at the node B becomes High, and the voltage at the node E also becomes High, so that the transistor TP1 remains OFF without being switched to ON. Therefore, even by applying a fuse element programming voltage to the programming voltage terminal VP1, and operating the signals LT, DATA, and CLK to control the shift register 13, such that the output voltage of the drive voltage conversion element 15 is set High, and the transistor TN1 turns ON, no programming voltage can be applied to the main memory unit 20, so that the fuse element Fa2 cannot be programmed. By operating the signals LT, DATA, and CLK to control the shift register 13, the output voltages of the drive voltage conversion element 15 and 16 are set Low and the voltages at the nodes C and D are set Low, whereby the transistors TN1 and TN2 are turned OFF, and the application of voltages to the read power supply terminal VR2 and the programming voltage terminal VP1 is stopped.

Thus, when the fuse element Fb1 is in a programmed state, the fuse element Fa2 cannot be programmed, whereby the information can be protected.

Even when the fuse elements Fb1 and Fb2 and the antifuse element Cb are in a programmed state, no programming voltage can be applied to the main memory unit 20, whereby the fuse element Fa2 can be protected from being programmed.

### (11) Protection Memory Programming Operation 1—Programming of Fuse Element Fb1

Referring to FIGS. 3A and 4K, a programming operation of the fuse element Fb1 will be described in a case where S_Fa1, S_Fa2,⋅S_Fb1, S_Fb2, S_Ca, and S_Cb are Low when the fuse elements Fa1, Fa2, Fb1, and Fb2 and the antifuse elements Ca and Cb are in an unprogrammed state.

First, when a fuse element programming voltage is applied to the programming voltage terminal VP2, the voltage of the programming voltage terminal VP2 is applied to the node B. Next, by operating the signals LT, DATA, and CLK to control the shift register 13, the output voltage of the drive voltage conversion element 16 is set High, and the output voltage at the node D is set High. Then, the transistor TN2 turns ON. Since the transistor TN2 turns ON, a current of 70 mA or more flows through the fuse element Fb1, whereby the voltage at the node B decreases to 0 V. At that time, the fuse element Fb1 generates heat, and eventually the fuse element Fb1 is blown. When the fuse element Fb1 is blown into an open state corresponding to a programmed state, no current flows through the fuse element Fb1, and the voltage at the node B increases to the voltage of the programming voltage terminal VP2. After the fuse element Fb1 is placed in a programmed state, the signals LT, DATA, and CLK are operated to control the shift register 13, whereby the output voltage of the drive voltage conversion element 16 is set Low, whereby the voltage at the node D becomes Low. Since the fuse element Fb1 is programmed, S_Fb1 becomes High. This causes the voltage at the node D to become Low, so that the transistor TN2 is turned OFF, and the application of the voltage to the fuse element Fb1 is stopped. Then, the application of the voltage to the programming voltage terminal VP2 is stopped.

This programming operation causes the circuit to change from the state shown in FIG. 3A to the state shown in FIG. 3B, in which the fuse element Fb1 is in a programmed state.

Thus, by bringing the fuse element Fb1 into a programmed state, the transistor TP1 turns OFF, whereby the application of the voltage of the programming voltage terminal VP1 to the main memory unit 20 is stopped, whereby the main memory unit 20 cannot be programmed, and the information can be protected.

### (12) Protection Memory Programming Operation 2—Programming of Antifuse Element Cb

Referring to FIGS. 3B and 4L, a programming operation of the antifuse element Cb will be described in a case where S_Fa1, S_Fa2, S_Fb2, S_Ca, and S_Cb are Low when the fuse elements Fa1, Fa2, and Fb2 and the antifuse elements Ca and Cb are in an unprogrammed state and S_Fb1 is High when only the fuse element Fb1 is in a programmed state.

First, when an antifuse element programming voltage is applied to the programming voltage terminal VP2, the programming voltage of the programming voltage terminal VP2 is applied to the node B. Next, by operating the signals LT, DATA, and CLK to control the shift register 13, the output voltage of the drive voltage conversion element 16 is set High, and the output voltage at the node D is set High. Then, the transistor TN2 turns ON. Since the transistor TN2 turns ON, the voltage of the programming voltage terminal VP2 is applied to the antifuse element Cb. Then, by operating the signals LT, DATA, and CLK to control the shift register 13, the output voltage of the drive voltage conversion element 16 is set Low, that is, the voltage at the node D is set Low, whereby the transistor TN2 is turned OFF, thereby removing the voltage applied to the antifuse element Cb. In the programming of the antifuse element Cb, an operation of applying a voltage to the antifuse element Cb for a predetermined time and then removing the applied voltage is repeatedly performed at a frequency of, for example, about 6 MHz, until the antifuse element Cb undergoes hard breakdown. When the antifuse element Cb undergoes hard breakdown, a current of about 10 to 30 mA flows, whereby the voltage at the node B decreases to the GND potential, and the programming of the antifuse element Cb completes. Since the antifuse element Cb is programmed, S_Cb becomes High. After a lapse of a predetermined time, by operating the signals LT, DATA, and CLK to control the shift register 13, the output voltage of the drive voltage conversion element 16 is set Low, whereby the transistor TN2 is turned OFF, and the application of the voltage to the programming voltage terminal VP2 is stopped.

By performing this programming operation, the circuit changes from the state shown in FIG. 3B to the state shown in FIG. 3E in which the antifuse element Cb is in a programmed state.

Thus, by bringing the fuse element Fb1 and the antifuse element Cb into a programmed state, the transistor TP1 turns ON, whereby the voltage of the programming voltage terminal VP1 is applied to the main memory unit 20, whereby the main memory unit 20 can be programmed.

### (13) Protection Memory Programming Operation 3—Programming of Fuse Element Fb2

Referring to FIGS. 3E and 4M, a programming operation of the fuse element Fb2 will be described in a case where S_Fa1, S_Fa2, S_Fb2, and S_Ca are Low when the fuse elements Fa1, Fa2, and Fb2 and the antifuse element Ca are in an unprogrammed state, and S_Fb1, and S_Cb are High when the fuse element Fb1 and the antifuse element Cb are in a programmed state.

First, when a fuse element programming voltage is applied to the programming voltage terminal VP2, the voltage of the programming voltage terminal VP2 is applied to the node B. Next, by operating the signals LT, DATA, and CLK to control the shift register 13, the output voltage of the drive voltage conversion element 16 is set High, and the output voltage at the node D is set High. Then, the transistor TN2 turns ON. Since the transistor TN2 turns ON, a current of 70 mA or more flows through the fuse element Fb2, whereby the voltage at the node B decreases to 0 V. At that time, the fuse element Fb2 generates heat, and eventually the fuse element Fb2 is blown. When the fuse element Fb2 is blown into an open state corresponding to a programmed state, no current flows through the fuse element Fb2, and the voltage at the node B increases to the voltage of the programming voltage terminal VP2. Since the fuse element is placed in a programmed state, S_Fb2 becomes High. After the fuse element Fb2 is placed in a programmed state, the signals LT, DATA, and CLK are operated to control the shift register 13, whereby the output voltage of the drive voltage conversion element 16 is set Low, whereby the voltage at the node D becomes Low, so that the transistor TN2 is turned OFF, and the application of the voltage to the fuse element Fb2 is stopped. Then, the application of the voltage to the programming voltage terminal VP2 is stopped.

This programming operation causes the circuit to change from the state shown in FIG. 3E to the state shown in FIG. 3G, in which the fuse element Fb2 is in a programmed state.

Thus, by placing the fuse elements Fb1 and Fb2 and the antifuse element Cb in a programmed state to set S_Fb1, S_Fb2, and S_Cb High, the transistor TP1 is not turned ON, whereby the voltage of the programming voltage terminal VP1 is not applied to the main memory unit 20, so that the main memory unit 20 cannot be programmed, and the information can be protected.

In the present embodiment, the main memory unit 20 and the programming protection control unit 21 are configured such that each includes one antifuse element and two fuse elements. However, if it is desired to change the number of times of programming protection, the number of antifuse elements and fuse elements in the main memory unit 20 and the programming protection control unit 21 may be changed.

Thus, programming of the OTP memory can be controlled by hardware, whereby the OTP memory cannot be programmed, thereby protecting the information from being erroneously programmed caused by an operational error or ESD.

### Third Embodiment

A third embodiment of the present disclosure illustrates a circuit configuration in which a main memory unit employs a single antifuse element, as an OTP memory element, and a programming protection control unit also employs a fuse element, which is an OTP memory.

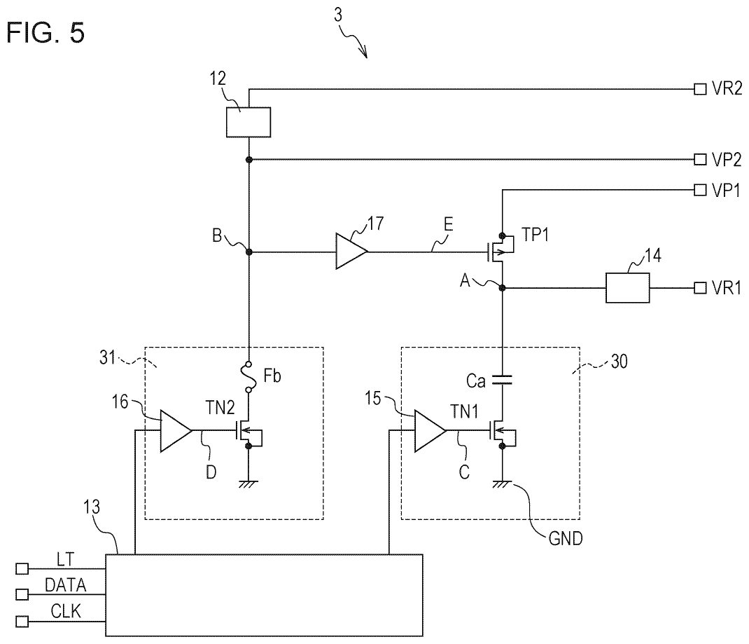

The third embodiment of the present disclosure will be described hereinbelow with reference to FIG. 5.

FIG. 5 illustrates a circuit configuration of a third semiconductor device 3 according to the third embodiment of the present disclosure, showing a state before information is programmed into the antifuse element and the fuse element.

The semiconductor device 3 according to the present embodiment includes a first semiconductor memory circuit including a main memory unit 30 having a transistor TN1, an antifuse element Ca, a drive voltage conversion element 15 configured to generate a drive voltage for the transistor TN1, and a node C; and a second semiconductor memory circuit including a protection control unit 31 having a transistor TN2, a fuse element Fb, a drive voltage conversion element 16 configured to generate a drive voltage for the transistor TN2, and a node D.

The semiconductor device 3 includes a read power supply terminal VR1 for the main memory unit 30, a read-power generation circuit 14 for the main memory unit 30, a voltage detection node A for the main memory unit 30, a programming voltage terminal VP1 for the main memory unit 30, a programming control transistor TP1 for the main memory unit 30, a transistor control circuit 17 configured to generate a drive voltage for the transistor TP1, and an output voltage detection node E for the transistor control circuit 17.

The semiconductor device 3 includes a read power supply terminal VR2 for the protection control unit 31, a read-power generation circuit 12 for the protection control unit 31, a voltage detection node B for the protection control unit 31, a programming voltage terminal VP2 for the protection control unit 31, a shift register 13 configured to generate driving signals for the main memory unit 30 and the protection control unit 31, signals LT, DATA, and CLK for controlling the shift register 13, and a ground wire GND.

In the present embodiment, when the fuse element Fb is in a programmed state, the antifuse element Ca is protected from being programmed.

Thus, programming of the OTP memory can be controlled by hardware, thereby protecting the programming information of the OTP memory from being erroneously programmed due to an operational error or ESD.

### Fourth Embodiment

A fourth embodiment of the present disclosure illustrates a circuit configuration in which an antifuse element, which is an OTP memory, is used as an OTP memory element for each of a main memory unit and a programming protection control unit for the main memory unit.

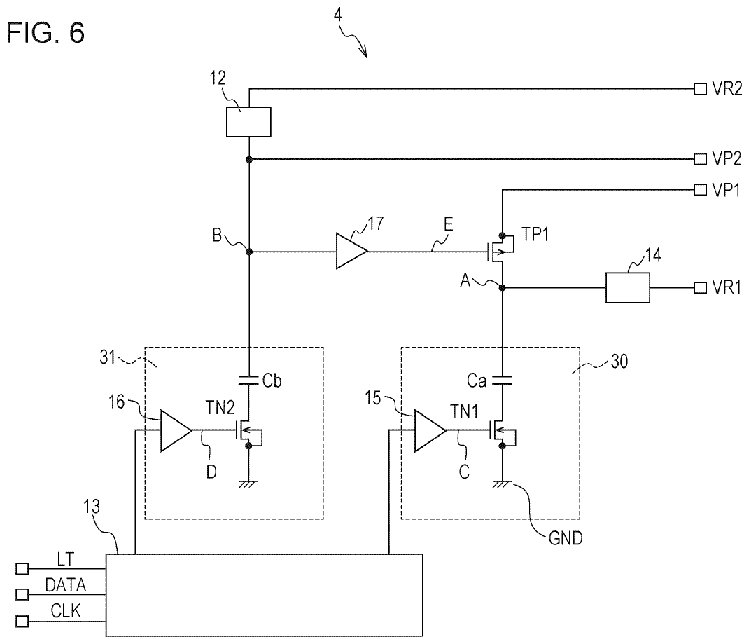

The fourth embodiment of the present disclosure will be described with reference to FIG. 6.

FIG. 6 illustrates a circuit configuration of a fourth semiconductor device 4 according to the fourth embodiment of the present disclosure, showing a state before information is programmed into the antifuse elements.

The fourth semiconductor device 4 according to the present embodiment includes a first semiconductor memory circuit including a main memory unit 30 having a transistor TN1, an antifuse element Ca, a drive voltage conversion element 15 configured to generate a drive voltage for the transistor TN1, and a node C; and a second semiconductor memory circuit including a protection control unit 31 having a transistor TN2, an antifuse element Cb, a drive voltage conversion element 16 configured to generate a drive voltage for the transistor TN2, and a node D.

The semiconductor device 4 includes a read power supply terminal VR1 for the main memory unit 30, a read-power generation circuit 14 for the main memory unit 30, a voltage detection node A for the main memory unit 30, a programming voltage terminal VP1 for the main memory unit 30, a programming control transistor TP1 for the main memory unit 30, a transistor control circuit 17 configured to generate a drive voltage for the transistor TP1, an output voltage detection node E for the transistor control circuit 17, a read power supply terminal VR2 for the protection control unit 31, a read-power generation circuit 12 for the protection control unit 31, and a voltage detection node B for the protection control unit 31.

The semiconductor device 4 includes a programming voltage terminal VP2 for the protection control unit 31, a shift register 13 configured to generate driving signals for the main memory unit 30 and the protection control unit 31, signals LT, DATA, and CLK for controlling the shift register 13, and a ground wire GND.

In the fourth semiconductor device 4 using antifuse elements as memories, information is recorded depending on whether the antifuse elements are in a conductive state or a non-conductive state, where the non-conductive state indicates an unprogrammed state and the conductive state indicates a programmed state.

In the present embodiment, when the antifuse element Cb is in a programmed state, the antifuse element Ca can be protected from being programmed.

### Fifth Embodiment

A fifth embodiment of the present disclosure illustrates a circuit configuration of a semiconductor device including a plurality of main memory units and having both a region with a programming protection function for the main memory units and a region without the programming protection function.

The programming protection function is implemented by a programming protection control unit that uses a plurality of OTP memories, such as fuse elements or antifuse elements, to enable rewriting, that is, to allow multiple switching between protection and cancellation of protection.

The main memory unit is also configured to be rewritable by using a plurality of fuse elements or antifuse elements, which are OTP memories, so that the information stored in the main memory unit is also rewritable.

By providing a main storage region with a programming protection function and a main storage region without a programming protection function to limit the main storage region that requires programming protection, an increase in cost due to an increase in the circuit size of the semiconductor device can be prevented.

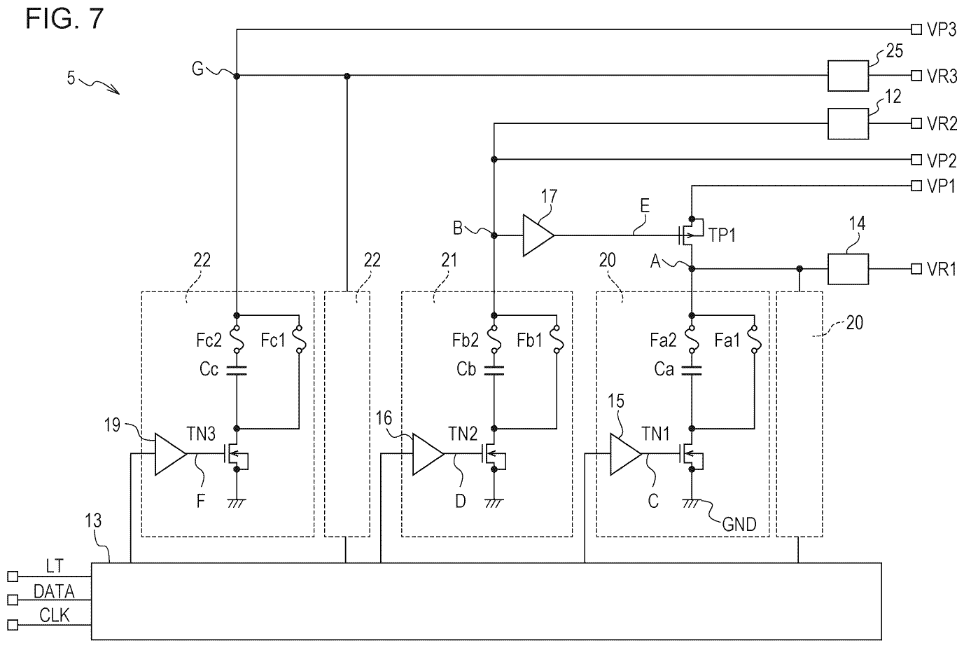

The fifth embodiment of the present disclosure will be described with reference to FIG. 7.

FIG. 7 illustrates a circuit configuration of a fifth semiconductor device 5 according to the fifth embodiment of the present disclosure, showing a state before information is programmed into the fuse elements and the antifuse elements.

The fifth semiconductor device 5 according to the present embodiment includes a plurality of main memory units 20 each including a transistor TN1, a fuse element Fa1, a fuse element Fa2, an antifuse element Ca, a drive voltage conversion element 15 configured to generate a drive voltage for the transistor TN1, and a node C; a programming protection control unit 21 including a transistor TN2, a fuse element Fb1, a fuse element Fb2, an antifuse element Cb, a drive voltage conversion element 16 configured to generate a drive voltage for the transistor TN2, and a node D; and a plurality of memory units 22 each including a transistor TN3, a fuse element Fc1, a fuse element Fc2, an antifuse element Cc, a drive voltage conversion element 19 configured to generate a drive voltage for the transistor TN3, and a node F.

The fifth semiconductor device 5 includes a read power supply terminal VR1 for the main memory units 20, a read-power generation circuit 14 for the main memory units 20, a voltage detection node A for the main memory units 20, a programming voltage terminal VP1 for the main memory units 20, a write control transistor TP1 for the main memory units 20, a transistor control circuit 17 configured to generate a drive voltage for the transistor TP1, an output voltage detection node E for the transistor control circuit 17, a read power supply terminal VR2 for the programming protection control unit 21, a read-power generation circuit 12 for the programming protection control unit 21, a voltage detection node B for the programming protection control unit 21, and a programming voltage terminal VP2 for the programming protection control unit 21.

The fifth semiconductor device 5 includes a read power supply terminal VR3 for the memory units 22, a read-power generation circuit 25 for the memory units 22, a voltage detection node G for the memory units 22, and a programming voltage terminal VP3 for the memory units 22.

The fifth semiconductor device 5 includes a shift register 13 configured to generate driving signals for the main memory units 20, the programming protection control unit 21, and the memory units 22, signals LT, DATA, and CLK for controlling the shift register 13, and a ground wire GND. In the fifth semiconductor device 5 using fuse elements and antifuse elements as memories, information is recorded depending on whether the fuse elements and the antifuse elements are in a conductive state or a non-conductive state. In the case of fuse elements, the conductive state indicates an unprogrammed state and the non-conductive state indicates a programmed state, whereas in the case of antifuse elements, the conductive state indicates a programmed state and the non-conductive state indicates an unprogrammed state.

In the present embodiment, the main memory units 20 have a programming protection function for storing information indicating whether to protect the information in the state of the programming protection control unit 21, and the memory units 22 have no programming protection function.

Thus, programming of the OTP memory can be controlled by hardware, thereby protecting the programming information of the OTP memory from being erroneously programmed due to an operational error or ESD.

### Sixth Embodiment

In the present embodiment, an application example of the semiconductor devices 1 to 5 according to the first to fifth embodiments will be described in which the fifth semiconductor device 5 is applied to a recording apparatus.

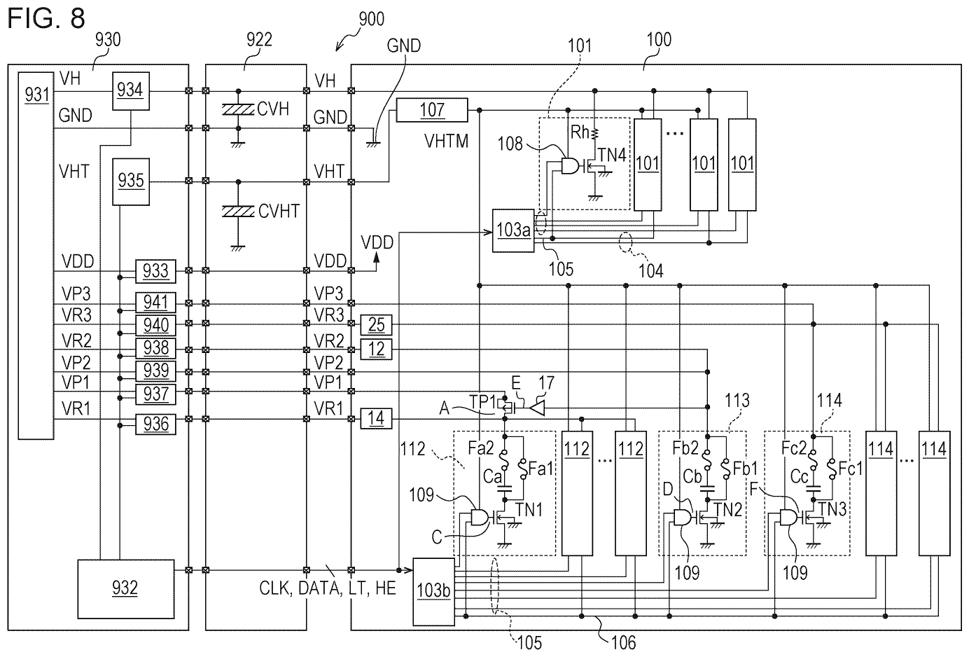

FIG. 8 illustrates an example of a control circuit of a recording apparatus 900 including a circuit configuration of a liquid-ejection recording element substrate 100 including the fifth semiconductor device 5 according to the fifth embodiment; a circuit configuration of a recording apparatus control board 930 configured to control the liquid-ejection recording element substrate 100; and a carriage board 922 configured to supply power and transfer signals from the recording apparatus control board 930 to the liquid-ejection recording element substrate 100.

The recording apparatus control board 930 includes a power generation circuit 931, a recording apparatus control circuit 932, a VDD control element 933, a VH control element 934, a VHT control element 935, a VR1 control element 936, a VP1 control element 937, a VR2 control element 938, a VP2 control element 939, a VR3 control element 940, and a VP3 control element 941.

The power generation circuit 931 supplies a first power-supply voltage VDD, a second power-supply voltage VH, a third power-supply voltage VHT, a fourth power-supply voltage VR1, a fifth power-supply voltage VP1, a sixth power-supply voltage VR2, a seventh power-supply voltage VP2, an eighth power-supply voltage VR3, a ninth power-supply voltage VP3, and a ground potential GND which are necessary for operating the recording apparatus 900.

The recording apparatus control circuit 932 is configured to control the recording apparatus 900 and controls: a clock signal CLK, an image data signal DATA, a latch signal LT, and a recording element control signal HE for controlling the liquid-ejection recording element substrate 100: a VDD control element 933 configured to control the output of the first power-supply voltage VDD; a VH control element 934 configured to control the output of the second power-supply voltage VH; a VHT control element 935 configured to control the output of the third power-supply voltage VHT; a VR1 control element 936 configured to control the output of the fourth power-supply voltage VR1; a VP1 control element 937 configured to control the output of the fifth power-supply voltage VP1; a VR2 control element 938 configured to control the output of the sixth power-supply voltage VR2; a VP2 control element 939 configured to control the output of the seventh power-supply voltage VP2; a VR3 control element 940 configured to control the output of the eighth power-supply voltage VR3; and a VP3 control element 941 configured to control the output of the ninth power-supply voltage VP3.

The carriage board 922 is configured to electrically connect signals and power between the liquid-ejection recording element substrate 100 and the recording apparatus control board 930.

The liquid-ejection recording element substrate 100 includes a recording unit 101; a recording element control circuit 103a; a memory control circuit 103b; a step-down circuit 107; a memory unit 112; a programming protection control unit 113; a memory unit 114; a first power-supply voltage VDD input terminal and a wiring circuit VDD; a second power-supply voltage VH input terminal and a wiring circuit VH; a third power-supply voltage VHT input terminal and a wiring circuit VHT; a fourth power-supply voltage VR1 input terminal and wiring; a read-power generation circuit 14 configured to generate a read supply voltage based on the fourth power-supply voltage VR1; a fifth power-supply voltage VP1 input terminal and wiring; a sixth power-supply voltage VR2 input terminal and wiring; a read-power generation circuit 12 configured to generate a read supply voltage based on the sixth power-supply voltage VR2; a seventh power-supply voltage VP2 input terminal and wiring; an eighth power-supply voltage VR3 input terminal and wiring; a read-power generation circuit 25 configured to generate a read supply voltage based on the eighth power-supply voltage VR3; a ninth power-supply voltage VP3 input terminal and wiring; a transistor TP1 configured to control application of the fifth power-supply voltage VP1 to the memory unit 112; a transistor control circuit 17 configured to control the transistor TP1 in the state of the programming protection control unit 113; a node A, a node B, a ground wire GND connection terminal; and a ground wire GND.

The step-down circuit 107 is configured to decrease the third power-supply voltage VHT to generate a tenth power-supply voltage VHTM.

The memory unit 112 includes a transistor TN1, a logical multiplication (AND) circuit 109 for driving the transistor TN1, fuse elements Fa1 and Fa2, an antifuse element Ca, and a node C. In the present embodiment, three memory units 112 are provided; however, three or more memory units 112 may be employed.

The programming protection control unit 113 includes a transistor TN2, a logical AND circuit 109 for driving the transistor TN2, fuse elements Fb1 and Fb2, an antifuse element Cb, and a node D. In the present embodiment, a single programming protection control unit 113 is provided; however, a plurality of programming protection control units 113 may be provided.

The memory unit 114 includes a transistor TN3, a logical AND circuit 109 for driving the transistor TN3, fuse elements Fc1 and Fc2, an antifuse element Cc, and a node F. In the present embodiment, three memory units 114 are provided; however, three or more memory units 114 may be provided.

The recording unit 101 includes a recording element (such as an electrothermal conversion element, a heater, or a piezoelectric element) Rh and a drive section configured to drive the recording element Rh (for example, a transistor TN4 and a logical AND circuit). By driving the recording element Rh, that is, by energizing the recording element Rh to generate heat, a recording agent is discharged from an ejection port, thereby performing recording. In the configuration example of the present embodiment, four recording units 101 are illustrated; however, four or more recording units 101 may be provided.

The recording element control circuit 103a and the memory control circuit 103b may be implemented by, for example, a shift register or a latch circuit. The recording element control circuit 103a and the memory control circuit 103b may receive, via a host personal computer (PC), the clock signal CLK, the image data signal DATA, the latch signal LT, and the heater control signal HE from the recording apparatus control circuit 932. The logical AND circuit 108, the logical AND circuit 109, the recording element control circuit 103a, and the memory control circuit 103b are supplied with the tenth power-supply voltage VHTM (for example, 3 to 5 V) as a power-supply voltage for driving the transistor.

Accordingly, the recording element Rh of the recording unit 101 and each memory unit 112 (semiconductor device) are electrically connected to the recording element control circuit 103a.

Here, the recording element control circuit 103a is configured to perform time-division driving of the recording element Rh by controlling the operation of the recording units 101 for each of m groups, each group having n recording units 101. The time-division driving can be performed by the recording element control circuit 103a through outputting an m-bit block selection signal 104 and an n-bit time-division selection signal 105.

The logical AND circuit 108 receives the corresponding block selection signal 104 and time-division selection signal 105, and, in response thereto, turns on the transistor TN4 to drive the recording element Rh connected in series with the transistor TN4. Here, the recording unit 101 is supplied with the second power-supply voltage VH (for example, 24 V) for driving the recording element Rh, and a ground potential is set as GND.

The logical AND circuit 109 receives a control signal 106 and the time-division selection signal 105, and outputs corresponding signals to the transistors TN1, TN2, and TN3, thereby switching the transistors TN1, TN2, and TN3 between a conductive state and a non-conductive state.

The liquid-ejection recording element substrate 100 receives the fourth power-supply voltage VR1 (for example, 3.3 V) for reading the information in the memory unit 112, the sixth power-supply voltage VR2 (for example, 3.3V) for reading the information of the programming protection control unit 113, the eighth power-supply voltage VR3 (for example, 3.3 V) for reading the information in the memory unit 114, the fifth power-supply voltage VP1 (for example, 24.0 V) for programming information into the memory unit 112, the seventh power-supply voltage VP2 (for example, 24.0 V) for programming information into the programming protection control unit 113, and the ninth power-supply voltage VP3 (for example, 24.0 V) for programming information into the memory unit 114, and the ground potential is set as GND.

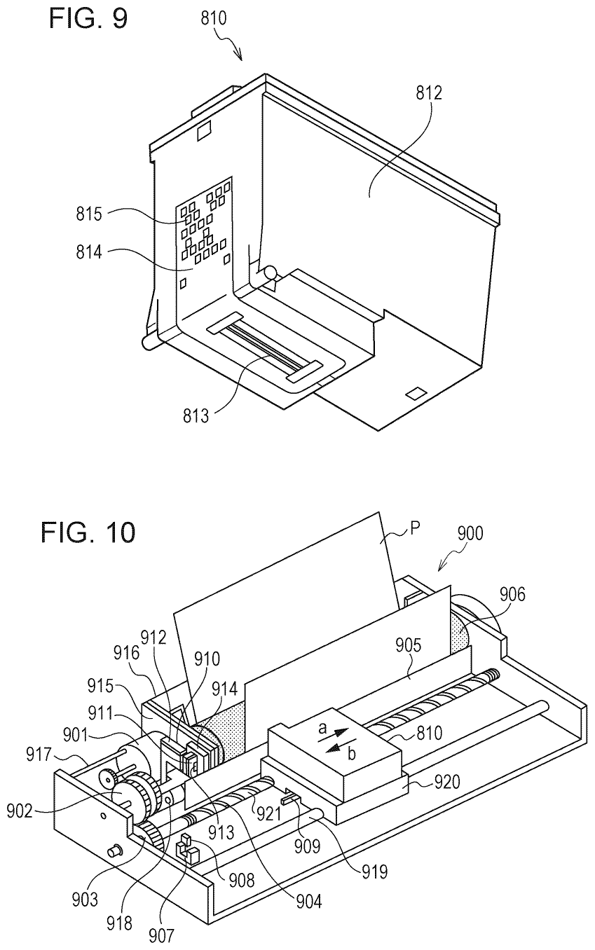

FIG. 9 is a perspective view of a liquid-ejection recording head 810 in the form of a liquid discharge head mountable on a recording apparatus. A recording element board 813 provided on the liquid-ejection recording head 810 and serving as a liquid discharge head is electrically connected, via a flexible film wiring board 814, to contact pads 815 that connect to the recording apparatus. Although the liquid-ejection recording head 810 shown in FIG. 9 is configured such that the recording element board 813 and an ink tank 812 are integrated, the head may alternatively be configured as a separate type in which the ink tank can be detached.

The liquid-ejection recording head 810 receives an electrical signal from the carriage board 922 mounted on a carriage 920 (FIG. 10) via the contact pads 815, and ejects ink in accordance with the electrical signal, thereby carrying out the above-described recording. The ink tank 812 includes an ink holding member, for example, a fibrous member or a porous member, and is configured to hold ink by means of the ink holding member.

FIG. 10 is a perspective view of the recording apparatus 900. The liquid-ejection recording head 810 is partly illustrated in FIG. 9 and is configured to be mounted on the carriage 920. The carriage 920 is configured to be mounted on a lead screw 904 having a spiral groove 921. By rotation of the lead screw 904, the liquid-ejection recording head 810 can be moved in the direction of arrow a or b along a guide 919 together with the carriage 920. The rotation of the lead screw 904 is linked to the rotation of a drive motor 901 through drive transmission gears 902 and 903.

Recording paper P, which is a recording medium, can be conveyed onto a platen 906 by a conveying unit. A bail plate 905 is configured to press the recording paper P against the platen 906 along the carriage moving direction. The recording apparatus 900 can detect the position of a lever 909 provided on the carriage 920 via photocouplers 907 and 908 and can switch the direction of rotation of the drive motor 901. A support member 910 is configured to support a cap member 911 for capping the nozzles of the liquid-ejection recording head 810. A suction unit 912 is configured to suck the inside of the cap member 911 and to perform a suction recovering process for the liquid-ejection recording head 810 through an in-cap opening 913.

A cleaning blade 914 is provided and a moving member 915 is configured to move the cleaning blade 914 in the back-and-forth direction. A body support plate 916 is configured to support the moving member 915 and the cleaning blade 914. A lever 917 may be provided to initiate a suction recovery process.

The lever 917 moves in association with the movement of a cam 918 that engages with the carriage 920. The driving force of the drive motor 901 may be controlled by transmission means such as switching of a clutch.

The recording apparatus 900 includes a recording control unit and is configured to control the driving of individual mechanisms in accordance with an electrical signal, such as recording data supplied from outside. The recording apparatus 900 repeats reciprocating movement of the liquid-ejection recording head 810 and conveyance of recording paper P by a conveying unit, thereby completing recording on the recording paper P.

Thus, programming of the OTP memory can be controlled by hardware, thereby protecting the programming information of the OTP memory from being erroneously programmed due to an operational error or ESD.

The above configuration enables prevention of erroneous programming of an OTP memory element caused by an operation error or electrostatic discharge, allowing for protection of information stored in the one-time programmable memory element.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-205848, filed Nov. 26, 2024, which is hereby incorporated by reference herein in its entirety.

What is claimed is:

1. A storage device comprising:
a first semiconductor memory circuit including a one-time programmable memory element; and
a second semiconductor memory circuit including a one-time programmable memory element,
wherein the one-time programmable memory element of the first semiconductor memory circuit is programmed based on information stored in the second semiconductor memory circuit.

2. The storage device according to claim 1, further comprising:
a first programming voltage terminal configured to apply a programming voltage to the first semiconductor memory circuit;
a transistor connecting the first semiconductor memory circuit to the first programming voltage terminal and configured to control application of the programming voltage; and
a transistor control circuit configured to switch between a conductive state and a non-conductive state, the transistor control circuit being provided between the first semiconductor memory circuit and the first programming voltage terminal,
wherein programming of the one-time programmable memory element of the first semiconductor memory circuit is based on the information stored in the second semiconductor memory circuit.

3. The storage device according to claim 2, wherein information stored in the first semiconductor memory circuit is protected from being programmed, based on the information stored in the second semiconductor memory circuit.

4. The storage device according to claim 2,
wherein the first semiconductor memory circuit is a main memory circuit configured to hold information, and
wherein the second semiconductor memory circuit is a programming protection control unit for the main memory circuit, the second semiconductor memory circuit being configured to change a state of the main memory circuit between a programmable state and a non-programmable state.

5. The storage device according to claim 2,
wherein the first semiconductor memory circuit includes a plurality of one-time programmable memory elements, and
wherein information stored in the first semiconductor memory circuit is rewritable.

6. The storage device according to claim 2,
wherein the second semiconductor memory circuit includes a plurality of one-time programmable memory elements, and
wherein information stored in the second semiconductor memory circuit is rewritable.

7. The storage device according to claim 1, wherein the one-time programmable memory element is a fuse element.

8. The storage device according to claim 1, wherein the one-time programmable memory element is an antifuse element.

9. The storage device according to claim 6,
wherein, in the second semiconductor memory circuit, the plurality of one-time programmable memory elements includes a first fuse element, a second fuse element, and an antifuse element,
wherein, the information stored in the second semiconductor memory circuit is rewritten based on programming of the first fuse element, the antifuse element, and the second fuse element in this order, and
wherein information stored in the first semiconductor memory circuit is protected to be rewritable or non-rewritable.

10. The storage device according to claim 1, further comprising a plurality of the first semiconductor memory circuits or a plurality of the second semiconductor memory circuits.

11. The storage device according to claim 10, wherein the plurality of first semiconductor memory circuits include:
a protected first semiconductor memory circuit, based on the information stored in the second semiconductor memory circuit, with information stored therein being rewritable or non-rewritable; and
another first semiconductor memory circuit configured to perform programming of the one-time programmable memory element independently of the information stored in the second semiconductor memory circuit.

12. A liquid-ejection recording element substrate comprising:
the storage device according to claim 1; and
a recording element configured to eject liquid.

13. A liquid-ejection recording head comprising:
the liquid-ejection recording element substrate according to claim 12; and
a liquid-ejection port.

14. A recording apparatus comprising:
the liquid-ejection recording head according to claim 13; and
a mechanism configured to convey a recording medium.
